(19) United States
(12) Patent Application Publication
(10) Pub. No.: US 2008/0241587 A1
(43) Pub. Date: Oct. 2, 2008

(54) Film-Forming Apparatus And Film-Forming Method

(75) Inventors: Tadahiro Ohmi, Miyagi (JP); Takaaki Matsuoka, Tokyo (JP)

Correspondence Address: FOLEY AND LARDNER LLP;SUITE 500, 3000 K STREET NW, WASHINGTON, DC, 20007, US

(73) Assignees: Tadahiro Ohmi; Tokyo Electron Limited

(21) Appl. No.: 10/594,495

(22) PCT Filed: Mar. 29, 2005
(86) PCT No.: PCT/JP05/05928

§ 371 Date: Nov. 7, 2006

(30) Foreign Application Priority Data
Mar. 29, 2004 (JP) 2004-097112

(51) Int. Cl. B05D 5/12; C23C 16/54; H01J 1/63

(52) U.S. Cl. 428/690; 118/724; 427/70

(57) ABSTRACT

For increasing the film-forming rate and enabling uniform film formation and waste elimination of raw material, a film-forming method and a film-forming apparatus can reach an evaporated film-forming material to a surface of a substrate by the flow of a transport gas so as to control the film-forming conditions by the flow of the gas. Thereby a uniform thin film can be deposited on the large-area substrate. That is, by directing the evaporated raw material toward the substrate, it is possible to increase the film-forming rate and achieve uniform film formation.

### TECHNICAL FIELD

This invention relates to a film-forming apparatus and a film-forming method for forming a film layer of a predetermined material and, in particular, relates to a film-forming apparatus and a film-forming method for forming a film layer of a predetermined material by evaporating a raw material of the predetermined material.

### BACKGROUND ART

Methods for forming a film layer of a predetermined material by evaporating a raw material of the predetermined material are widely used in the manufacture of such electronic devices as semiconductor devices, flat panel display devices and others. As one example of such electronic devices, description will be given hereinbelow of an organic EL display device. The organic EL display device with sufficiently high brightness and a lifetime of several tens of thousands of hours or more uses an organic EL element that is a self-luminous element and thus can be formed thin with less peripheral components such as a backlight. Therefore, the organic EL display device is ideal as a flat panel display device. The organic EL element forming such an organic EL display device is required, in terms of characteristics as the display device, such that, while being a large screen, the element lifetime is long, there are no variations in luminous brightness on the screen and in element lifetime, there are no defects typified by dark spots, and so on. Film formation of an organic EL layer is quite important for satisfying those requirements.

As a film-forming apparatus for uniformly forming a film of an organic EL layer on a large substrate, use is comprised of an apparatus described in Patent Document 1 or the like. The film-forming apparatus of Patent Document 1 is intended to ensure uniformity of the film thickness on a large substrate by optimally arranging in a tree fashion the piping structure inside an injector located in the apparatus.

An organic EL layer currently is formed by a vacuum deposition apparatus at 10⁻⁶ Torr to 10⁻⁷ Torr or less. According to an experiment by the inventors, it has been clarified that, in a current organic EL vacuum deposition apparatus, an organic EL layer is subjected to a large amount of organic contamination in an organic EL layer forming process, so that the brightness and lifetime of an organic EL light emitting diode (OLED) are largely reduced. FIG. 1 shows a sectional structure of a green light emitting OLED used in the experiment. A glass substrate 10 has a thickness of 0.3 to 1.0 mm, an ITO transparent electrode 102 (work function −4.80 eV) has a thickness of 100 to 150 mm, an ITO layer 103 has a thickness of 5 to 10 mm and a work function controlled to approximately −5.2 eV by adding V (vanadium) to approximately several percents, a hole transport layer (NPD) 104 has a thickness of approximately 40 nm, a light emitting layer (Alq3) 105 has a thickness of approximately 40 nm, an electron injection cathode electrode (MgAg) 106 (work function −3.7 eV) likewise has a thickness of approximately 40 nm, a metal electrode (Ag) 107 has a thickness of approximately 100 nm, and a SiO₂ protective film 108 has a thickness of 3 to 5 μm and is adapted to prevent invasion of moisture and so on from the atmosphere. Light is extracted on the glass substrate 101 side. The emission wavelength is approximately 520 nm. The ITO transparent electrodes 102 and 103 were sputter-deposited at a temperature of approximately 250° C. and then annealed in a N₂ gas atmosphere at 300° C. The NPD 104 and Alq3 105 of organic EL films were formed by deposition in a vacuum of approximately 1×10⁻⁷ Torr.

A graph of black circles in FIG. 2 shows results of forming films of the NPD layer, the Alq3 layer, and the MgAg electrode layer immediately after transfer of the glass substrate in a continuous vacuum deposition apparatus of a shape provided with a load lock chamber (assuming that the load lock chamber is also set in a vacuum of approximately 1×10⁻⁷ Torr). A graph of black triangles in FIG. 2 shows results of leaving the substrate standing in an atmosphere of approximately 1×10⁻⁷ Torr for 30 minutes when film formation of the respective layers. The current value was 15 mA/cm². The brightness of the sample exposed to the atmosphere of approximately 1×10⁻⁷ Torr for 30 minutes at the time of the film formation of the respective layers was changed to approximately ⅓ and the lifetime in which the brightness was degraded to half was reduced to ⅓ or less.

As a result of repeating assiduous studies about the foregoing lifetime degradation, the inventors of this invention have found that since, in the vacuum state, the partial pressure of organic compound components serving as a source of contamination increases and simultaneously the mean free path of organic compound molecules increases overwhelmingly, organic compound contamination on the substrate surface becomes quite large to thereby reduce the lifetime of the organic EL element.

Further, it has been ascertained that uniformity in film quality and film thickness at the time of the film formation of the organic EL element is quite important for reducing variations in luminous brightness on the screen and in element lifetime. As a film-forming apparatus for uniformly depositing an organic EL thin film, the apparatus described in Patent Document 1 is cited as an example. However, although the film thickness of an organic EL element formed in the apparatus of such a structure is uniform, dark spots or variation in element lifetime occurs.

Further, according to the injector described in Patent Document 1, there arises a problem that since there is no disclosure about the material and temperature of the injector, the organic EL material is deposited inside the injector and decomposed inside the injector depending on the conditions, thereby causing deposition of the decomposition product on the substrate, so that the organic EL element does not function.

Patent Document 1: Japanese Unexamined Patent Application Publication JP-2004-79904-A2

### DISCLOSURE OF THE INVENTION

### Problem to be Solved by the Invention

The conventional film-forming method has a problem that since, basically, the raw material is evaporated from an evaporation dish and adhered to the substrate without directionality (i.e. with non-directionality), the film formation takes time and further it is difficult to form a uniform film. This problem is more serious for film formation on a substrate with an increased area, which is one of the industrial features in recent years. For example, approximately 4 minutes are required for forming a single-color organic EL layer on a glass substrate having a size of 400 mm×500 mm, because, since it is composed of a hole injection layer, a hole transport layer, a light emitting layer, an electron injection layer, and so on, it is necessary to carry out film formation of as many as several organic compound layers. Further, as long as approximately 20 minutes are required for completing formation of a three-color organic EL layer including times for transfer, mask changes, and so on, thereby an increase in cost has been caused.

Further, the conventional film-forming method has a problem that since the evaporated raw material is dispersed without directionality, it is also adhered to portions other than the substrate and hence there is much waste. There is also a problem that since the evaporation continues for some time even after heating of the evaporation dish is stopped, a waste of the raw material occurs during non-film formation. For example, since the organic EL film-forming raw material is expensive, these problems are even more serious.

Therefore, an object of this invention is to provide a film-forming apparatus and a film-forming method that can increase the film-forming rate and enable uniform film formation by directing an evaporated raw material toward a substrate.

Another object of this invention is to provide a film-forming apparatus and a film-forming method that are highly economical with a waste of raw material eliminated.

Another object of this invention is to provide a film-forming apparatus and a film-forming method that can carry out film formation on a large-area substrate at a high rate and highly economically.

Still another object of this invention is to provide a film-forming apparatus and a film-forming method with suppressed organic compound contamination.

### Means for Solving the Problem

According to this invention, there is obtained a film-forming apparatus for depositing a film of a predetermined material on a substrate, the film-forming apparatus characterized by comprising a container to be depressurized, a depressurizing means directly or indirectly coupled to the container, first holding means located in the container for holding a raw material used for forming the film of the predetermined material, second holding means located in the container for holding the substrate, evaporation means located in the container for evaporating the raw material, and transport gas-supplying means located in the container for supplying a gas so as to transport the evaporated raw material to the surface of the substrate. In the foregoing apparatus, it is preferable that the evaporation means include means for heating the raw material to a first temperature equal to or higher than a temperature at which the raw material is evaporated and a predetermined portion inside the container be heated to a second temperature exceeding the temperature at which the raw material is evaporated.

Further, in this invention, according to the foregoing film-forming apparatus, there is obtained the film-forming apparatus characterized by further comprising means for maintaining the temperature of the substrate at a third temperature lower than the temperature at which the raw material is evaporated, the film-forming apparatus characterized in that the first temperature and the second temperature are lower than a temperature at which the evaporated raw material is decomposed, or the film-forming apparatus characterized in that the second temperature is higher than the first temperature. It is preferable that the second temperature be higher than the first temperature by 20° C. or more. Further, in the foregoing film-forming apparatus, it is preferable that the third temperature be equal to or lower than the temperature at which the raw material is evaporated, that the predetermined material be an organic EL material and the third temperature be less than 100° C., and that the predetermined portion is a portion adapted to contact the evaporated raw material and excluding the substrate and the second holding means.

In this invention, according to the foregoing film-forming apparatus, there is obtained the film-forming apparatus characterized in that the first holding means is a heat-resistant container for holding the predetermined material or a precursor of the predetermined material, or the film-forming apparatus characterized in that the transport gas-supplying means comprises a gas container placing the first holding means therein and means for introducing the gas into the gas container, and further, the gas container includes a gas ejection portion having a plurality of small holes and located at a portion forming an outlet of the gas so as to face the substrate, so that the gas transports the evaporated raw material to the surface of the substrate through the gas ejection portion. In this case, the predetermined portion includes the gas container. This invention includes other features, respectively, that the transport gas-supplying means includes means for supplying the gas during execution of film formation and stopping supply of the gas during non-execution of film formation, that the evaporation means includes means for evaporating the raw material during the execution of film formation and stopping evaporation of the raw material during the non-execution of film formation, and that the means for heating includes means for heating the raw material to the first temperature during the execution of film formation and heating, during the non-execution of film formation, the raw material to a fourth temperature less than the temperature at which the raw material is evaporated, wherein the difference between the first temperature and the fourth temperature is preferably set to 70° C. to 150° C. It is preferable that the depressurizing means includes means for maintaining the inside of the container at a pressure of 10 mTorr to 0.1 mTorr during the execution of film formation and maintaining the inside of the container at a reduced pressure of 1 Torr or more at least for a certain period during the non-execution of film formation and that the depressurizing means includes means for causing a gas flow in the container to be in a molecular flow region during the execution of film formation and causing a gas flow in the container to be in an intermediate flow region or a viscous flow region at least for a certain period during the non-execution of film formation.

According to this invention, in the foregoing film-forming apparatus, the gas is preferably a xenon (Xe) gas. Alternatively, it is preferable that the gas contain an inert gas as a main component and the inert gas contain at least one of nitrogen (N), Xe, Kr, Ar, Ne, and He, and that the transport gas-supplying means contain means for setting the temperature of the gas to a temperature equal to the first temperature or equal to or higher than the first temperature at least at the stage before transporting the evaporated raw material. It is preferable that the gas container be comprised of a material whose release gas is small in amount or the gas container be comprised of a material whose catalytic effect is small.

The predetermined material or its precursor is preferably exemplified by an organic EL element material and is not particularly limited, but use can be comprised of, for example, 1,1-bis(4-di-paminophenyl)cyclohexane, carbazole or its derivative, triphenylamine or its derivative, quinolinol aluminum complex containing dopant, DPVi biphenyl, silole derivative, cyclopentadien derivative, or an organic EL material for red, blue, or green emission.

In the film-forming apparatus of this invention, the depressurizing means comprises a turbo-molecular pump and a roughing vacuum pump and inert gas-supplying means is preferably provided between the turbo-molecular pump and the roughing vacuum pump in terms of suppressing back diffusion of an exhaust gas to the process chamber. The inert gas preferably contains at least the transport gas component and is more preferably the same gas.

A gasket used in the film-forming apparatus of this invention is preferably comprised of a material whose organic compound release is small in amount, and is exemplified by an organic compound gasket whose release gas is small in amount, an organic compound gasket having been subjected to a step of contacting it with water of 80° C. or more and cleaned, a metal gasket, or the like. The organic compound gasket whose release gas is small in amount is preferably a gasket containing a perfluoroelastomer as a main component. The organic compound gasket is suitable for maintaining air-tightness at a portion with a relatively high attaching/detaching frequency, such as a door for substrate-frequency.

Further, a film-forming apparatus of this invention comprises, at least, a container to be depressurized, a depressurizing means directly or indirectly coupled to the container, film-forming material supply means located inside or outside the container and directly or indirectly coupled to the container for supplying a film-forming material or a film-forming material precursor, and substrate placing means located in the container for placing a substrate to be deposited with the film-forming material, the film-forming apparatus characterized in that the film-forming material supply means has at least evaporation means such as a crucible for evaporating the film-forming material or the film-forming material precursor and the evaporation means is comprised of a material whose release gas is small in amount.

Further, a film-forming apparatus of this invention comprises, at least, a container to be depressurized, a depressurizing means directly or indirectly coupled to the container, film-forming material supply means located inside or outside the container and directly or indirectly coupled to the container for supplying a film-forming material or a film-forming material precursor, and substrate placing means located in the container for placing a substrate to be deposited with the film-forming material, the film-forming apparatus characterized in that the film-forming material supply means has at least evaporation means such as a crucible for evaporating the film-forming material or the film-forming material precursor and the evaporation means is comprised of a material whose catalytic effect is small.

Further, a film-forming apparatus of this invention is a film-forming apparatus coupled to a substrate transfer apparatus and is characterized in that an air having a dew point temperature of −80° C. or less is supplied to a space inside the substrate transfer apparatus. By this, it is possible to reduce the substrate-adsorbed moisture amount and thus suppress contamination of film-forming environment.

Further, a film-forming apparatus of this invention is characterized in that the pressure in a container to be depressurized during film formation and that during non-film formation are in a molecular flow pressure region and an intermediate flow pressure region or a viscous flow pressure region, respectively.

The material whose release gas is small in amount in this invention exhibits the state where when a comparison is made between a generated gas amount of the subject material at a film-forming material evaporation temperature and a generated gas amount of a SUS-316L material, having the same shape as that of the subject material and having the electrolytically polished surface, at such a temperature, the generated gas amount of the former is equal to or less than the generated gas amount of the latter, or the state where the partial pressure, exhibited by a generated gas when a constituent component of a film-forming apparatus is formed by the use of the subject material and located in the film-forming apparatus, is equal to or less than 1/10 of a film-forming pressure. The material conforming to either of them is preferable and the material conforming to both is more preferable.

The material whose catalytic effect is small in this invention exhibits the state where when a comparison is made between a decomposition temperature of a film-forming material or a film-forming material precursor measured when the subject material is brought into contact with the film-forming material or the film-forming material precursor and raised in temperature and a decomposition temperature of the film-forming material or the film-forming material precursor measured when a SUS-316L material having the same shape as that of the subject material and having the electrolytically polished surface is brought into contact with the film-forming material or the film-forming material precursor and raised in temperature, the material composition temperature of the former is equal to or higher than the material decomposition temperature of the latter or the state where when a comparison is made between a decomposition start temperature exhibited by the film-forming material or the film-forming material precursor alone and a decomposition start temperature exhibited when the subject material is brought into contact with the film-forming material or the film-forming material precursor, the difference of the temperature of the latter with respect to the temperature of the former is 20° C. or less. The material conforming to either of them is preferable and the material conforming to both is more preferable.

According to another mode of this invention, there is obtained a film-forming method for depositing a film of a predetermined material on a substrate in a container to be depressurized, the film-forming method characterized by comprising a step of evaporating a raw material used for forming the film of the predetermined material and a step of transporting the evaporated raw material to a surface of the substrate by the use of a gas. In the foregoing film-forming method, it is characterized in that the evaporating step comprises a step of heating the raw material to a first temperature equal to or higher than a temperature at which the raw material is evaporated, and a predetermined portion inside the container is heated to a second temperature exceeding the temperature at which the raw material is evaporated. It is characterized in that the temperature of the substrate is maintained at a third temperature lower than the temperature at which the raw material is evaporated. This invention also includes other features, respectively, that the first temperature and the second temperature are lower than a temperature at which the evaporated raw material is decomposed, that the second temperature is higher than the first temperature, that the second temperature is higher than the first temperature by 20° C. or more, that the third temperature is equal to or lower than the temperature at which the raw material is evaporated, that the predetermined material is an organic EL material and the third temperature is less than 100° C., that the predetermined portion is a portion adapted to contact the evaporated raw material and excluding the substrate, and that the raw material is the predetermined material or a precursor of the predetermined material.

In this invention, there is also obtained a film-forming method characterized by placing the raw material in a heat-resistant container, placing the heat-resistant container in a gas container, and introducing the gas into the gas container, wherein a gas ejection portion having a plurality of small holes is provided at a portion forming an outlet of the gas container so as to face the substrate, thereby causing the gas to reach the surface of the substrate through the gas ejection portion while transporting the evaporated raw material. This invention also includes features of heating the gas container to the second temperature, of supplying the gas during execution of film formation and stopping supply of the gas during non-execution of film formation, of evaporating the raw material during the execution of film formation and stopping evaporation of the raw material during the non-execution of film formation, of heating the raw material to the first temperature during the execution of film formation and heating, during the non-execution of film formation, the raw material to a fourth temperature less than the temperature at which the raw material is evaporated, of setting the difference between the first temperature and the fourth temperature to 70° C. to 150° C., of maintaining the inside of the container at a pressure of 10 mTorr to 0.1 mTorr during the execution of film formation and maintaining the inside of the container at a reduced pressure of 1 Torr or more at least for a certain period during the non-execution of film formation, and of causing a gas flow in the container to be in a molecular flow region during the execution of film formation and causing a gas flow in the container to be in an intermediate flow region or a viscous flow region at least for a certain period during the non-execution of film formation. In the foregoing film-forming method, it is preferable that the gas be a xenon (Xe) gas, that the gas contain an inert gas as a main component, that the inert gas contain at least one of nitrogen (N), Xe, Kr, Ar, Ne, and He, and that the temperature of the gas be set to a temperature equal to the first temperature or equal to or higher than the first temperature at least at the stage before transporting the evaporated raw material.

According to this invention, there are obtained an organic EL device manufacturing method characterized by including a step of forming a film of an organic EL element material by the use of the foregoing film-forming apparatus or film-forming method, and an electronic device manufacturing method characterized by including a step of forming a layer of a predetermined material by the use of the foregoing film-forming apparatus or film-forming method. Further, there are obtained an organic EL device having an organic EL layer formed by the use of the foregoing film-forming method and an electronic device having a layer of a predetermined material formed by the use of the foregoing film-forming method.

### EFFECT OF THE INVENTION

According to this invention, since an evaporated film-forming material reaches the surface of a substrate by the flow of a transport gas, the film-forming conditions can be controlled by the flow of the gas and hence a uniform thin film can be deposited on the large-area substrate. That is, by directing the evaporated raw material toward the substrate, it is possible to increase the film-forming rate and achieve uniform film formation. For example, approximately one to two minutes are enough for forming a three-color organic EL layer on a glass substrate having a size of 400 mm×500 mm and hence the film-forming time can be shorted to 1/10 or less as compared with conventional. By directing the evaporated raw material toward the substrate, by raising the temperature of a portion other than the substrate to an evaporation temperature or more to prevent unnecessary adhesion of the evaporated raw material, or by using a heavy gas such as xenon for transport so as to fix the flow of the raw material in a constant direction, the expensive raw material can be selectively adhered only on the substrate, thereby enabling highly economical film formation with a waste of the raw material eliminated. Further, since use is comprised of the method that transfers the evaporated film-forming material on the flow of the transport gas, it is possible to stop ejection of the raw material by stopping the flow of the gas during non-film formation and hence it is possible to prevent generation of waste of the raw material.

The film-forming apparatus of this invention thoroughly eliminates generation of the organic compound contamination substance/material decomposition dissociation substance that adversely affects the properties of the film-forming material, and thus can deposit a high-quality thin film. By using the film-forming apparatus of this invention for forming an organic EL element, it is possible to obtain a high-quality organic EL display device with high brightness and long lifetime.

### BRIEF DESCRIPTION OF THE DRAWINGS

FIG. 1 is a diagram showing a sectional structure of a green light emitting OLED.

FIG. 2 is a graph showing the time dependence of luminous intensities of OLEDs.

FIG. 3 is a graph showing the mean free paths of neutral gas atoms.

FIG. 4 is a graph showing the time dependence of organic compound amounts adsorbed on the surfaces of substrates left standing in a depressurizing apparatus and a clean room.

FIG. 5 is a graph showing the storage pressure dependence of organic compound adhered to the surfaces of wafers.

FIG. 6 is a graph showing the chamber-fed N₂ gas flow rate dependence of adsorption organic amounts on the surfaces of substrates at a storage pressure of 3 Torr.

FIG. 7 is a graph showing the time dependence of adsorption organic compound amount on the surface of a substrate in a vacuum state of 7.5×10⁻⁸ Torr.

FIG. 8 is a graph showing the temperature dependence of ion currents of mass numbers 28, 43, and 57 measured by a quadrupole mass spectrometer in a chamber at a pressure of 7.5×10⁻⁸ Torr where a SiO₂ coated silicon substrate adhered with eicosane (C₂₀H₄₂) is located.

FIG. 9 is a graph showing the pressure dependence of ion currents of mass numbers 28, 43, and 57 by the use of a quadrupole mass spectrometer when the pressure in a chamber is changed by a N₂ gas while maintaining the temperature constant.

FIG. 10 is a graph showing the temperature dependence of ion currents, by the use of a quadrupole mass spectrometer, of mass numbers 43 and 57 being dissociated molecules of eicosane (C₂₀H₄₂) in an atmospheric vacuum atmosphere of 7.5×10⁻⁸ Torr.

FIG. 11 is a graph showing the time dependence of substrate surface adsorption amounts of C₂₀H₄₂ molecules when the pressure in a chamber is changed to 90 Torr, 10 Torr, and 3 Torr.

FIG. 12A is a graph showing characteristics of C₂₀H₄₂ molecules and is the graph showing surface equilibrium adsorption amounts of substrate surface adsorption.

FIG. 12B is a graph showing characteristics of C₂₀H₄₂ molecules and is the graph showing the pressure dependence of adsorption time constant.

FIG. 13 is a graph showing the pressure dependence of substrate surface adsorption amounts of C₂₀H₄₂ molecules when the exposure time of the surfaces of substrates is changed to seven kinds from 1 minute to 400 minutes.

FIG. 14A is a graph showing the molecular weight dependence of adsorption amount in the case of straight-chain hydrocarbon adsorbed on the substrate surface at room temperature under the atmospheric pressure.

FIG. 14B is a graph showing the molecular weight dependence of adsorption amount in the case of phthalate ester adsorbed on the substrate surface at room temperature under the atmospheric pressure.

FIG. 14C is a graph showing the molecular weight dependence of adsorption amount in the case of cyclic siloxane adsorbed on the substrate surface at room temperature under the atmospheric pressure.

FIG. 15 is a schematic diagram showing the structure of a gas exhaust system of a reduced-pressure deposition apparatus.

FIG. 16 is a graph showing the relationship between chamber pressure and gas flow rate given to a chamber.

FIG. 17A is a diagram showing a molecular structure of Alq3.

FIG. 17B is a diagram showing a molecular structure of NPD.

FIG. 18 is a diagram showing a schematic structure of an experimentation system for evaluating dissociation of Alq3 molecules.

FIG. 19 is a graph showing FT-IR absorption spectra of evaporated Alq3 at (a) and FT-IR absorption spectra of solid Alq3 at (b), respectively.

FIG. 20 is a graph showing FT-IR absorption spectra of water molecules (H₂O) and a CO₂ gas.

FIG. 21 is a graph showing IR spectra identification of Alq3.

FIG. 22 is a graph showing the temperature dependence of respective Alq3 peaks.

FIG. 23 is a graph showing comparison between infrared absorption spectra of NPD in a gas phase at (a) and in a solid phase at (b).

FIG. 24 is a graph showing infrared absorption spectra of NPD molecules.

FIG. 25 is a graph showing the temperature dependence of respective NPD peaks in the evaporation dish.

FIG. 26 is a sectional view showing a schematic structure of an organic film-forming apparatus.

FIG. 27 is a graph for explaining Cu elution amounts in various waters.

FIG. 28 is a diagram for explaining the structure of a temperature control cooling water circulation system.

FIG. 29 is a diagram for explaining the shape of a cooling pipe.

FIG. 30 is a diagram for explaining the structure of a temperature control cooling water circulation system.

FIG. 31 is a diagram showing a section of an organic compound molecule ejection apparatus portion.

FIG. 32 is a diagram showing the structure of a substrate upward type organic film-forming apparatus.

FIG. 33 is a diagram showing the structure of a substrate sideward type organic film-forming apparatus.

FIG. 34 is a diagram showing the structure of an organic film-forming apparatus having a Xe or Kr gas recovery circulation system.

FIG. 35 is a diagram showing the structure of a Kr circulation supply apparatus.

FIG. 36 is a diagram showing the structure of a Xe circulation supply apparatus.

FIG. 37 is a diagram showing the structure of an Ar/Kr circulation supply apparatus.

FIG. 38 is a diagram showing the structure of an Ar/Xe circulation supply apparatus.

FIG. 39A is a sectional view showing the structure of a gas levitation transfer apparatus.

FIG. 39B is a perspective view showing the structure of the gas levitation transfer apparatus.

FIG. 40 is an exemplary diagram for schematically explaining a section of a film-forming apparatus.

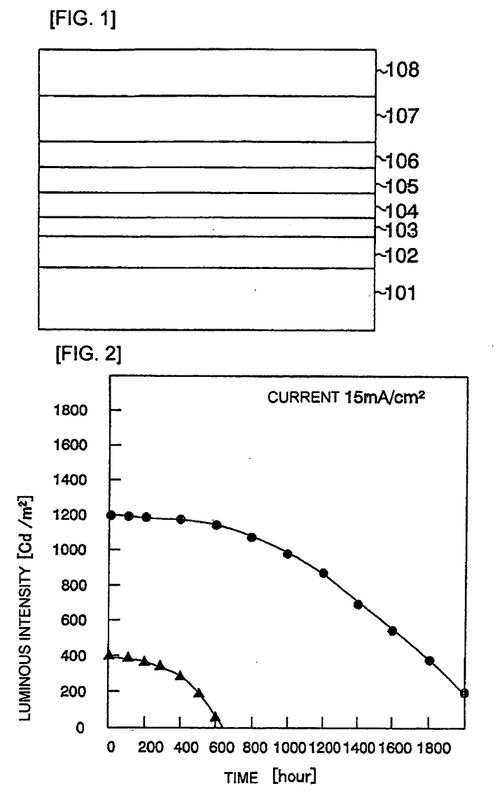

### BEST MODE FOR CARRYING OUT THE INVENTION

Hereinbelow, description will be given of facts clarified by the inventors of this invention.

(Contamination from the Atmosphere)

FIG. 3 shows the gas pressure dependence of the mean free paths of Ar (mass number 40), Kr (mass number 80), and Xe (mass number 131) being typical gases. The mean free path increases in inverse proportion to the pressure and decreases when gas atoms/molecules increase in weight or the collision cross section increases. The mean free path normally reaches several hundred meters at 1×10⁻⁷ Torr. It is well known that when the surface of a substrate is exposed to air in a clean room, a large amount of organic compound is adsorbed thereon.

(State of Contamination Under Reduced Pressure)

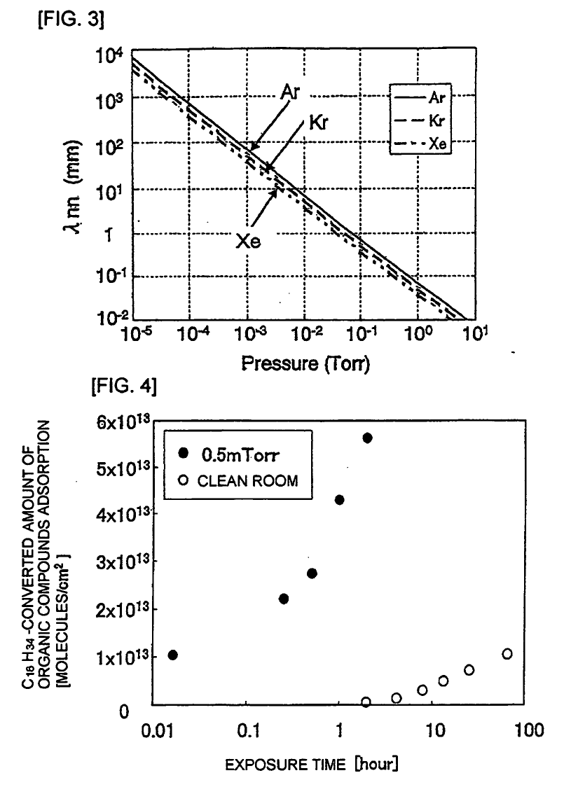

FIG. 4 shows the time dependence of organic compound adsorption on the surfaces of thermal oxide film (SiO₂) coated silicon substrates when the substrates were exposed in a clean room at room temperature T and in a substrate transfer chamber is depressurized to 1 mTorr or less. The organic compound adsorbed on the substrate surfaces was measured by a thermal desorption gas chromatograph/mass spectral method. The organic compound adsorption amount is indicated in terms of straight-chain hydrocarbon hexadecane (C₁₆H₃₄, CH₃(CH₂)₁₄CH₃: molecular weight 226). FIG. 4 shows that the adsorption amount of organic compound is much greater under vacuum reduced pressure which has been considered a clean atmosphere. The origins of such organic compound are components adsorbed on the inner surfaces of the chamber from the atmosphere when the inside of the chamber is exposed to the atmosphere, evaporation of grease or the like applied to mechanical sliding portions for substrate transfer or the like, evaporation from plastic O-rings for maintaining the atmospheric vacuum reduced pressure, back diffusion, to the chamber, of evaporated components of grease on the secondary side of a gas exhaust pump coupled for vacuum evacuation, and so on.

<Organic compound Adsorption Mechanism under Reduced Pressure≦

Description will be next given of organic compound adsorption behavior onto the surface of a substrate under reduced pressure.

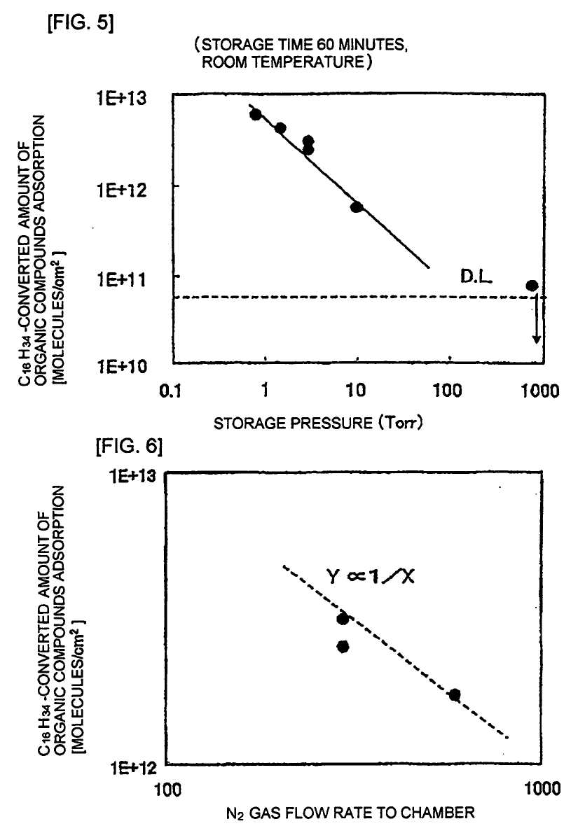

FIG. 5 shows the storage pressure dependence of surface-adsorbed organic compound amounts when thermal oxide film coated silicon substrates treated with a 0.5% HF solution for 5 minutes and rinsed with ultrapure water for 20 minutes were exposed to atmospheres of 0.8 Torr to 10 Torr at room temperature for 60 minutes. The storage pressure was controlled by setting the N₂ gas flow rate constant at 300 cc/min and changing the pumping speed of an exhaust pump.

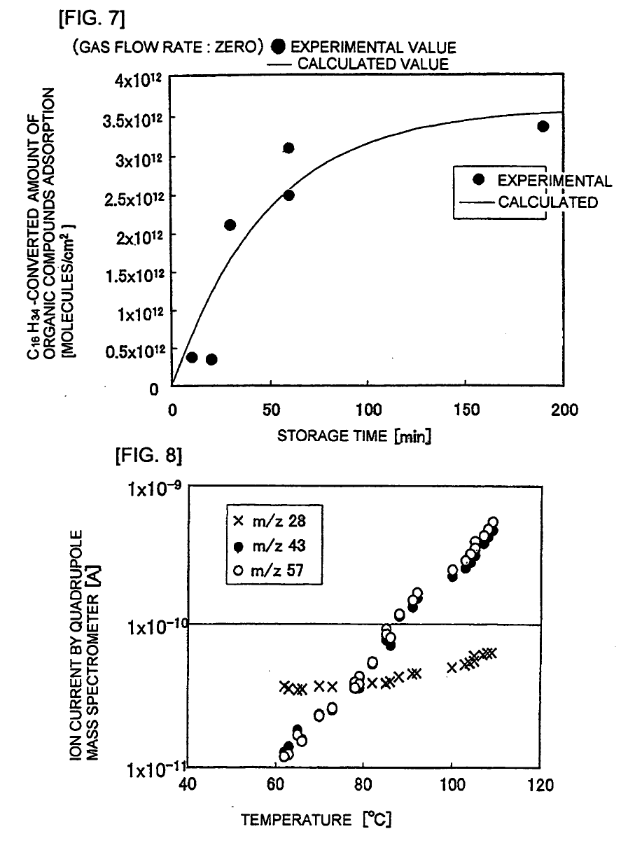

Even in the viscous flow region of 0.8 Torr to 10 Torr, when the pressure decreases so that the partial pressure of organic compound increases and the mean free path increases, the adsorption organic compound amount increases in inverse proportion to the storage pressure. FIG. 6 shows measurement results of adsorption organic compound amounts on the surfaces of substrates when the gas flow rate to a chamber was increased to 500 cc/min from 300 cc/min while fixing the storage pressure at 3 Torr in the same experiment. The results of FIG. 6 show that the adsorption organic compound amount decreases in inverse proportion to the increase in gas flow rate even under the same storage pressure. That is, by increasing the gas flow rate to reduce the partial pressure of organic compound, the adsorption organic compound amount decreases even when the mean free path of organic compound molecules is the same. It has already been made clear that substrate surface adsorption of organic compound molecules at the atmospheric pressure can be described by the Langmuir monomolecular adsorption model. How will it be under vacuum or reduced pressure? FIG. 7 shows the time dependence of organic compound amount adsorbed on the surface of a thermal oxide film coated silicon substrate left standing at a vacuum pressure of 7.5×10⁻⁸ Torr (gas flow rate: zero). In FIG. 7, there are shown calculated values of time variation of an adsorption organic compound amount C (molecules/cm²) based on the Langmuir monomolecular adsorption model

C(t)=Ce(1−10^{-t/τ}) (1)

where Ce represents a surface equilibrium adsorption amount (molecules/cm²) and τ an adsorption time constant. The results of FIG. 7 show that the adsorption of organic compound onto the substrate surface can be described by the Langmuir monomolecular adsorption model even under vacuum or reduced pressure.

Next, description will be given of the temperature/pressure dependence of organic compound amounts evaporated from organic compound adsorbed on the inner surfaces of a chamber, grease, plastics, and O-rings. FIG. 8 shows ion currents of mass numbers 28, 43, and 57 measured by a quadrupole mass spectrometer when the temperature is changed in the state where a thermal oxide film coated silicon substrate adhered with eicosane (C₂₀H₄₂:CH₃(CH₂)₁₈CH₃: molecular weight 282, vapor pressure at 25° C.: 9.1×10⁻⁵ mmHg, melting point 36° C., boiling point 237 to 240° C.) being straight-chain hydrocarbon is located in a chamber maintained at 7.5×10⁻⁸ Torr. The ion current of mass number 28 represents N₂ molecules being the residue of the atmosphere, while the ion currents of mass numbers 43 and 57 represent ion currents of dissociated components of the eicosane (C₂₀H₄₂: molecular weight 282). Although the N₂ molecule ion current hardly depends on the temperature, the C₂₀H₄₂ ion currents increase exponential-functionally along with the temperature rise.

On the other hand, FIG. 9 shows the pressure dependence of ion voltages of mass numbers 28, 43, and 57 likewise by the quadrupole mass spectrometer when the pressure in the chamber is changed from 7.5×10⁻⁸ Torr to 3×10⁻⁶¹ Torr by a N₂ gas while maintaining the temperature constant. FIG. 9 shows that even if the pressure (total pressure) in the chamber is changed by approximately two digits, the pressure of C₂₀H₄₂ does not change at all. That is, it has been confirmed that the vapor pressure of organic compound molecules (C₂₀H₄₂ in this case) depends only on the temperature and does not depend on the pressure.

A vapor pressure Pv of organic compound molecules to the gas phase is normally described by the Antonie equation. That is,

Pv=10^{A}×10^{-B/(C+T(° C.))} (2)

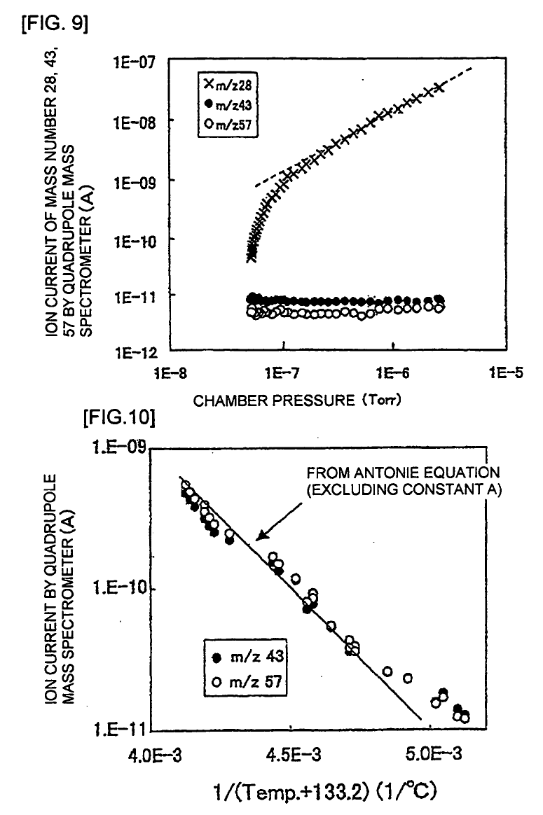

FIG. 10 shows the results of replotting the results of C₂₀H₄₂ in FIG. 8 so as to match the Antonie equation. The results of FIG. 10 show that, given that A=7.0664, B=1,994.0° C., and C=133.2° C., the vapor pressure of C₂₀H₄₂ can be accurately expressed by the Antonie equation. It has been confirmed that the vapor pressure of organic compound molecules adsorbed on the surfaces or included in the materials hardly depends on the pressure of an atmosphere but depends only on the temperature so as to increase exponential-functionally along with the temperature rise and can be described almost accurately by the Antonie equation. Therefore, it is important for designing/manufacturing a manufacturing apparatus to have a structure where the temperatures of grease-applied portions and resin O-ring portions are maintained as low as possible to thereby suppress the evaporation of organic compound molecules.

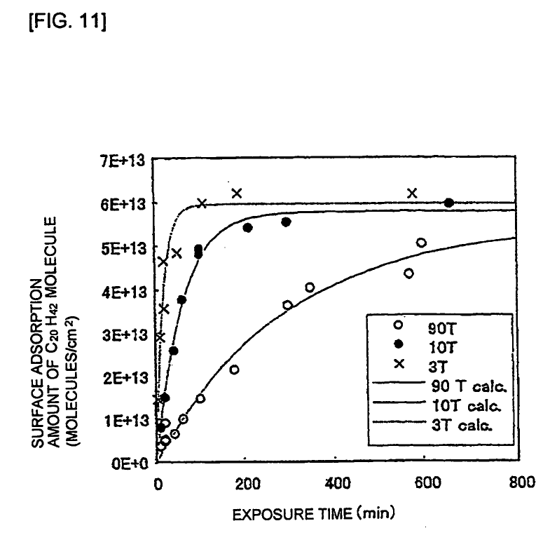

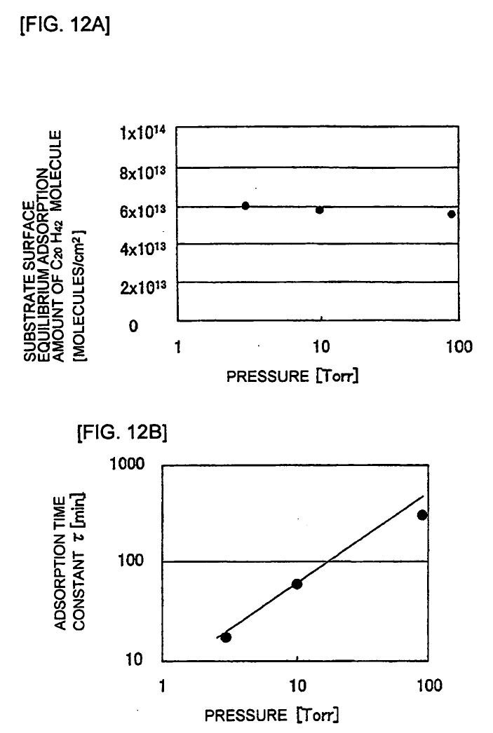

It was possible to clarify the evaporation behavior of eicosane (C₂₀H₄₂) as described above. FIG. 11 shows the results of inserting SiO₂ coated silicon substrates with clean surfaces in the same chamber and examining the atmospheric pressure dependence of C₂₀H₄₂ molecule adsorption onto the clean silicon substrate surfaces. In FIG. 11, there is shown the exposure time dependence of the numbers of C₂₀H₄₂ molecules adsorbed on the clean SiO₂ coated silicon substrates when the pressure in the chamber is changed to three kinds, i.e. 90 Torr, 10 Torr, and 3 Torr. It is clear from FIG. 11 that the surface equilibrium adsorption amount hardly changes even if the pressure in the chamber changes and that the adsorption time constant decreases along with the pressure drop. Surface equilibrium adsorption amounts Ce (molecules/cm²) and adsorption time constants τ(min) derived from the foregoing Equation (1) of the Langmuir monomolecular adsorption are shown in Table 1 and the pressure dependence thereof is shown in FIGS. 12A and 12B. It has been made clear that the adsorption time constant decreases as the pressure decreases so that the partial pressure of C₂₀H₄₂ molecules increases and the mean free path increases.

[Table 1]

TABLE 1
Surface Equilibrium Adsorption Amounts Ce and Adsorption
Time Constants τ at Respective Pressures

| Pressure | | Ce (molecules/cm²) | τ(min) |
|---|---|---|---|
| 90 | Torr | 5.54E+13 | 300.0 |
| 10 | Torr | 5.76E+13 | 59.5 |
| 3 | Torr | 5.94E+13 | 17.3 |

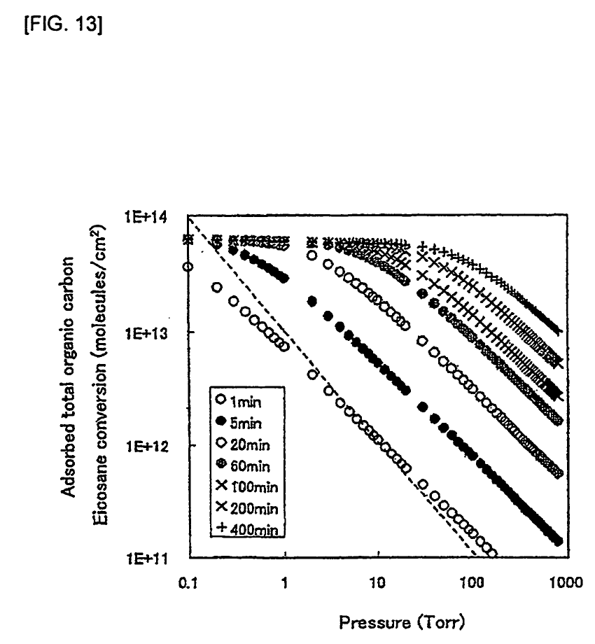

FIG. 13 shows the atmospheric pressure dependence of substrate surface adsorption amounts of C₂₀H₄₂ molecules when the exposure time of the surfaces of substrates is changed to seven kinds from 1 minute to 400 minutes.

The technique has become obvious that thoroughly suppresses organic compound molecule adsorption onto the substrate surface for ultrahigh-quality process management.

(1) To suppress as low as thoroughly possible the partial pressure of organic compound molecules in a process chamber and a substrate transfer chamber.

(2) To maintain as high as possible the pressure to a process chamber and a substrate transfer chamber within the range where no inconvenience occurs.

(3) To shorten as much as possible the residence time of a substrate in a process chamber and a substrate transfer chamber in a depressurized state.

Organic compound contamination sources in the depressurizing chamber relating to item (1) are (a) resin O-rings for use in maintaining hermetic sealing, (b) grease for use in lubricating sliding portions (it is a principle to eliminate sliding portions in the chamber as much as possible), (c) back diffusion of oil from the outlet side of a gas exhaust pump, (d) organic compound adsorption onto the inner surfaces of the chamber from the atmosphere when the inside of the chamber is exposed to the atmosphere, and (e) organic compound adsorption onto the front and back surfaces of a substrate from the atmosphere.

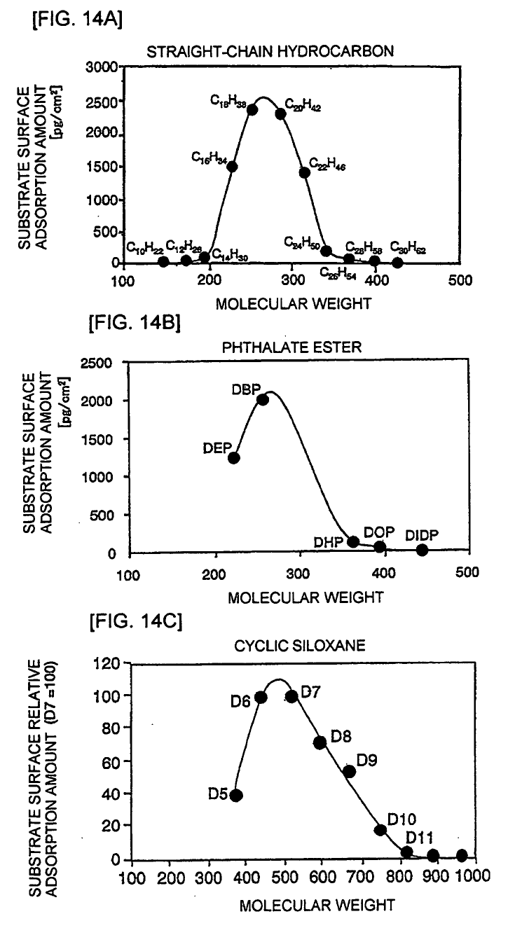

There is no alternative but to use the resin O-ring of item (a) at a portion that is repeatedly opened and closed, like a gate valve provided at a substrate carry-in or carry-out portion. Organic compound released from plastics is in the form of molecules having a relatively small molecular weight. FIGS. 14A to 14C show the results of examining adsorption amounts on the surfaces of substrates at room temperature under the atmospheric pressure by changing the molecular weights of straight-chain hydrocarbon (CₙH₂ₙ₊₂), phthalate ester, and cyclic siloxane, respectively.

An organic compound molecule having a small molecular weight is not adsorbed on the surface of the substrate because its adsorption/desorption activation energy is small. Since the organic compound molecule having a molecular weight greater than a certain value (approximately 400 in the case of straight-chain hydrocarbon or phthalate ester and approximately 900 in the case of cyclic siloxane) is not released into the gas phase because its vapor pressure is small, it is not adsorbed on the substrate. Naturally, as the temperature rises, the critical molecular weight of organic compound released into the gas phase shifts to the greater side more and more. Use should be comprised of an O-ring of a resin that contains no low-molecular-weight organic compound that is released into the gas phase and adsorbed on the substrate surface (e.g. DU351 manufactured by Daikin Industries, Ltd.). With respect also to the grease in item (b), use should be comprised of one that contains no low-molecular-weight organic compound that is released into the gas phase.

It is desirable that there be no mechanical sliding portions and the temperature of an O-ring using grease or a grease-using portion be set as low as possible. When using it at high temperature, since the release critical molecular weight shifts to the higher side, taking it into account, organic compound having a molecular weight of 800 or less is not contained in the case of straight-chain hydrocarbon or phthalate ester, organic compound having a molecular weight of 1500 or less is not contained in the case of cyclic siloxane, and so on.

In order to suppress the back diffusion, into the chamber, of organic compound emitted from grease at a pump gear portion in item (c), it is necessary to feed to a purge port a high purity gas such as Ar or N₂ which does not adversely affect a process even if it flows backward into the chamber, so that the pressure of the portion where gears and so on using the grease are present never drops to the molecular flow region but is surely controlled in the viscous flow region.

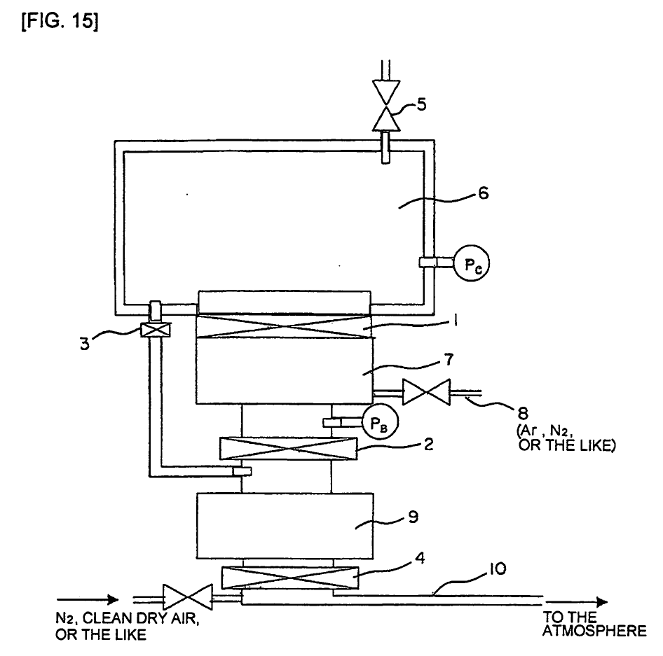

FIG. 15 shows a pump system coupled to a chamber 6 of an organic film-forming apparatus. In FIG. 15, there are included valves 1 to 5, the chamber 6, a turbo-molecular pump 7, a purge port 8, a roughing vacuum pump 9, and an exhaust duct 10.

The high-vacuum evacuation turbo-molecular pump 7 (pumping speed S₁ (litter/sec)) is coupled to the chamber 6 through the gate valve 1 (butterfly valve or the like) and is coupled to the roughing vacuum pump 9 (pumping speed S₂ (litter/min)) through the valve 2. An Ar or N₂ gas, which does not affect a process even if it flows backward into the chamber 6, is fed to the purge port 8 of the turbo-molecular pump 7. The roughing vacuum pump 9 is directly coupled to the chamber 6 through the valve 3. The roughing vacuum pump 9 is coupled to the exhaust duct 10 through the valve 4 and an exhaust gas is discharged into the atmosphere from the exhaust duct 10. A N₂ gas or a clean dry air containing no moisture or organic compound is fed to the downstream side of the valve 4 so as to prevent the atmospheric components containing moisture and so on from entering the exhaust duct 10 or the roughing vacuum pump 9 while the apparatus is stopped.

During organic film formation, the inside of the chamber is set to a gas pressure from the transition flow region to the molecular flow region where the mean free path of molecules becomes several centimeters or more. As clear from FIG. 3, it is the gas pressure of 1 mTorr or more. During this film formation, the valve 1 is opened while the valve 3 is closed, thereby carrying out the gas exhaust by the use of the turbo-molecular pump 7 and the roughing vacuum pump 9. While an organic film is not formed and a substrate is carried in or out, the pressure inside the chamber 6 is set to the viscous flow region of 1 Torr or more. By setting the pressure to preferably 5 Torr or more and more preferably 10 Torr or more, the partial pressure of contaminants is relatively reduced and the mean free path thereof is shortened. In this event, the valve 1 is closed, the valve 3 is opened, and the valve 5 at a gas introducing portion is opened. Given that the gas flow rates are f₁ (cc/min) (gas introducing portion flow rate) and f₂ (cc/min) (turbo-molecular pump purge port flow rate), the pumping speeds of the pumps are S₁ (litter/sec) (turbo-molecular pump) and S₂ (litter/min) (roughing vacuum pump), and the pressure inside the chamber is Pc (Torr), relational equations thereof are

f₁+f₂=79Pc S₂/60 (3)

during non-film formation, and

f₁=79PcS₁ (4)

f₁+f₂=79P_{B}S₂/60 (5)

during film formation, where P_{B} represents a pressure on the downstream side of the turbo-molecular pump.

For example, given that S₁=12,000 litter/sec and S₂=2,400 litter/min in terms of film formation on a large glass substrate, metal substrate, or the like, even if it is set that f₁=2,000 cc/min and f₂=1,600 cc/min during non-film formation, the chamber pressure Pc during non-film formation only becomes approximately 1 Torr from the foregoing equation (3). If the valve 3 is throttled to set the effective pumping speed of the roughing vacuum pump 9 to 1/10, i.e. 240 litter/min, the chamber pressure Pc becomes approximately 10 Torr.

During film formation, the valve 3 is closed and the valve 1 is opened. Given that the gas flow rates at that time are f₁=1,000 cc/min and f₂=1,600 cc/min, the chamber pressure Pc is 1.05 mTorr from the foregoing equation (4) and P_{B} on the downstream side of the turbo-molecular pump 7 is 0.82 Torr.

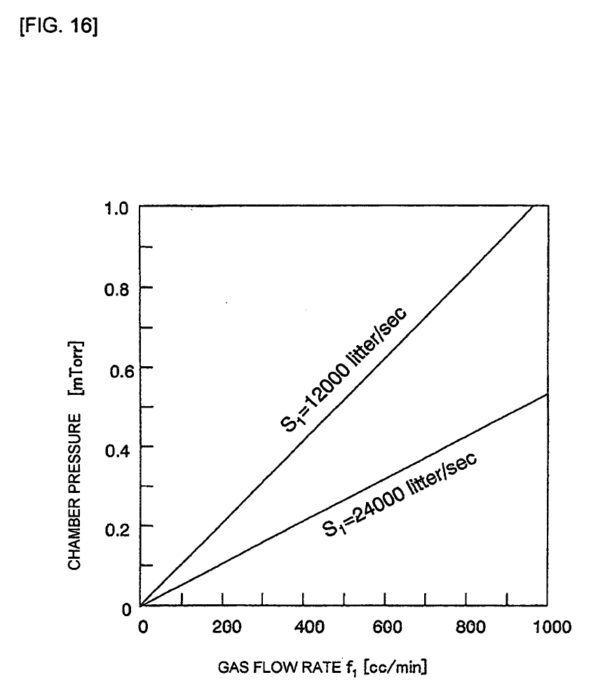

FIG. 16 shows the relationship between the gas flow rate fed to the chamber 6 in FIG. 15 and the chamber pressure. Naturally, if the pumping speed of the turbo-molecular pump 7 is set to double, i.e. 24,000 litter/sec, the chamber pressure Pc becomes half so as to be 0.52 mTorr in the transition flow region when f₁=1,000 cc/min. If the valve is throttled to f₁=200 cc/min, the chamber pressure Pc becomes 0.1 mTorr so that the mean free path of gas molecules increases to approximately several tens of centimeters.

The method of suppressing the organic compound contamination has been described above. Next, the organic film-forming technique will be described in detail.

Since an organic EL material is raised in temperature so as to be evaporated and formed a film on an opposing glass substrate, metal substrate, or the like, it is quite important not to decompose/dissociate organic EL molecules when the temperature is raised. There are two causes for decomposition/dissociation of the organic EL molecules. One is the decomposition/dissociation due to a catalytic effect exhibited by the surface in contact with the organic EL molecules when the temperature rises to a certain level. The other is the decomposition/dissociation due to oxidative decomposition caused by moisture (H₂₀) or oxygen (O₂) adsorbed/occluded to/in the organic EL material. Therefore, before supplying the organic EL material into an evaporation film-forming container, it is necessary to place the organic EL material on a porous carbon heater and raise the temperature from 150° C. to approximately 220° C. to 230° C. by causing a high purity N₂ gas (the content of H₂₀ and O₂ is 100 ppb or less and preferably 10 ppb or less) to flow through porous carbon, thereby removing the adsorbed/occluded moisture and oxygen.

Next, description will be given of what has been clarified about a material with the least catalytic effect which is optimal for evaporating and gasifying the organic EL material.

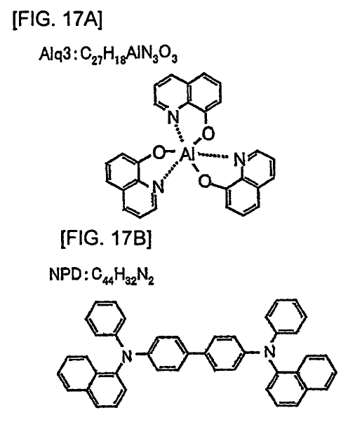

Description will be given of the results of Alq3 (C₂₇H₁₈AlN₃O₃) and NPD (C₄₄H₃₂N₂) as typical organic EL materials. The molecular weights, melting points, and glass transition temperatures of Alq3 and NPD are 459.43 and 588.74, none due to sublimation properties and 280° C., and 175° C. and 96° C., respectively. FIGS. 17A and 17B show molecular structures of Alq3 and NPD. Molecules of Alq3 and NPD are evaporated to be gas molecules when raised to 270° C. to 300° C. or more.

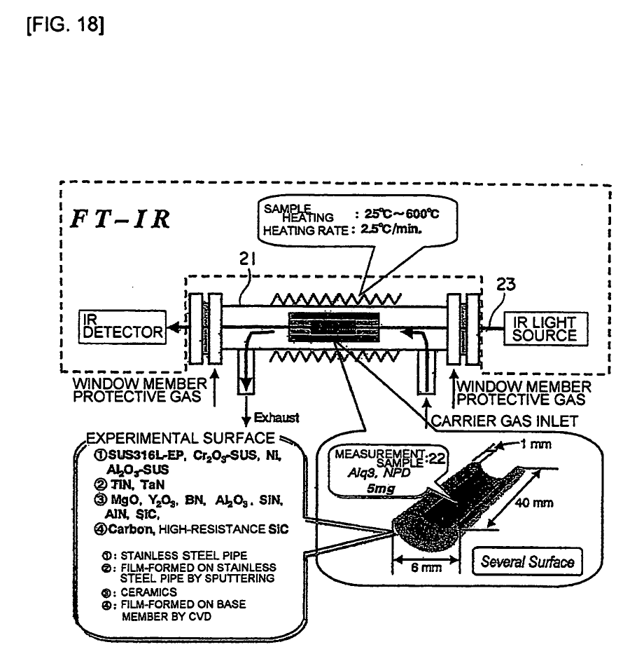

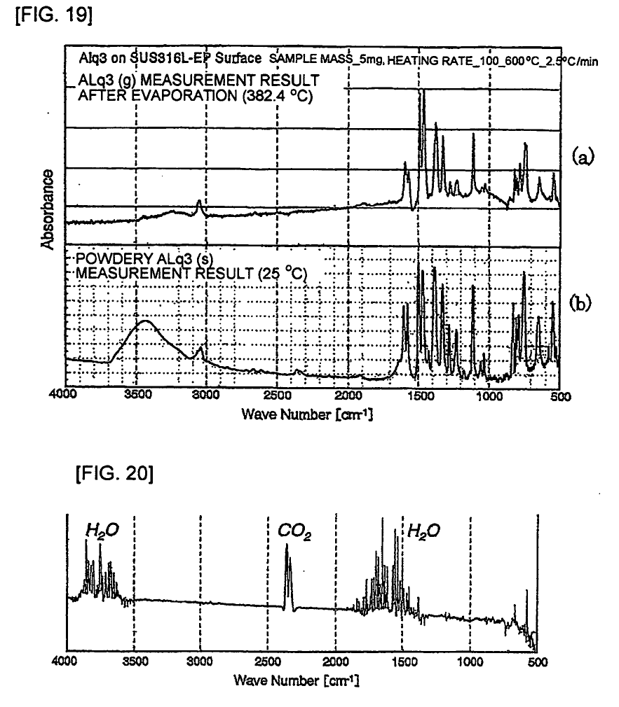

Evaporation dishes having the surfaces of various measurement samples 22 are inserted into a tube furnace 21 shown in FIG. 18 and the temperature of the tube furnace is raised while feeding a N₂ gas, thereby detecting infrared absorption spectra of the evaporated measurement sample 22, for example, Alq3 molecules, by the use of an FT-IR. The tube furnace 21 is a ½-inch stainless pipe. The N₂ gas is fed at 5 cc/min in order to prevent deposition of Alq3 molecules on a window member and the N₂ gas is fed to the tube furnace 21 at 10 cc/min. The speed of the N₂ gas flowing in the tube furnace 21 is 2.8 mm/sec at room temperature (25° C.) and 7.2 mm/sec at 500° C. The temperature of the tube furnace 21 is raised from 25° C. to 600° C. by 2.5° C./min. FIG. 19, (a) and (b) show FT-IR absorption spectra when the temperature of the tube furnace 21 is raised to 382.4° C. and FT-IR absorption spectra of solid Alq3 when Alq3 powder is formed into a thin layer. Although the peaks are observed only in solid Alq3 near 3400 cm⁻¹ and near 2400 cm⁻¹, the other peaks basically coincide with each other in both. Gasified Alq3 is not decomposed/dissociated.

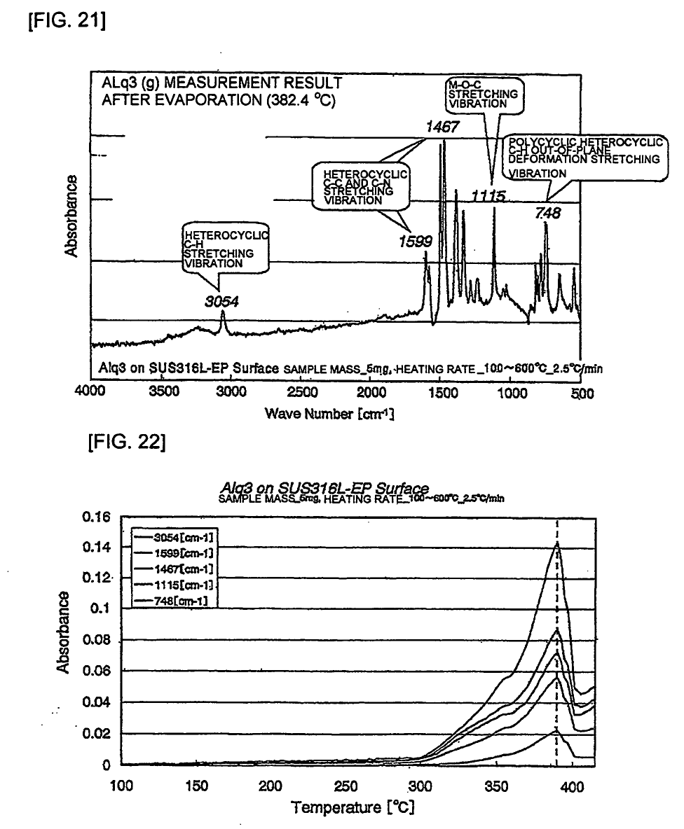

FIG. 20 shows FT-IR absorption spectra of moisture (H₂₀) and a CO₂ gas. There is a high possibility that the spectra near wave numbers of 3400 cm⁻¹ and 2400 cm⁻¹ in (b) of FIG. 19 are caused by moisture or CO₂ adsorbed on solid Alq3. FIG. 21 shows identification of the FT-IR absorption spectra of Alq3 gasified at 382.4° C. FIG. 22 shows the temperature dependence of intensities of respective absorption spectra (3054 cm⁻¹, 1599 cm⁻¹, 748 cm⁻, 1115 cm⁻¹, and 1467 cm⁻¹) of Alq3 molecules in order from lower. When the temperature exceeds 300° C., Alq3 molecules evaporated into the gas phase gradually increase, but, at a temperature of 390.1° C., all the absorption spectra rapidly decrease. This is because the Alq3 molecules start to be decomposed/dissociated due to the catalytic effect of the electrolytically polished surface of stainless (SUS316L used for the evaporation dish. Since the temperature of the evaporation dish should be raised for providing a large amount of Alq3 in the gas phase, the decomposition/dissociation temperature is desirably as high as possible.

Table 2 shows temperatures of decomposition/dissociation of Alq3 molecules with different surface materials of the evaporation dishes for evaporating Alq3. Resistance values of various materials in Table 2 are values measured by pushing resistance measurement terminals against various surfaces at a distance of 1 cm therefrom.

[Table 21]

TABLE 2
Decomposition/Dissociation Temperatures of Alq3 Molecules
according to Evaporation Dish Surface Materials

| Alq3 | Temperature [° C.] | Resistance | |
|---|---|---|---|
| Carbon | 422.5 | 2 | Ω/cm |
| SiC | 412.7 | 400 | Ω/cm |
| TaN | 409.5 | 0.8 | Ω/cm |
| AlN | 409.4 | 4000 | MΩ/cm or more |
| BN | 408.2 | 4000 | MΩ/cm or more |
| TiN | 405.1 | 0.2 | Ω/cm |
| MgO | 404.9 | 4000 | MΩ/cm or more |
| Si₃N₄ | 403.0 | 4000 | MΩ/cm or more |
| Al₂O₃—SUS | 402.0 | 0.3 | Ω/cm |
| High-Resistance SiC | 401.8 | 10 | MΩ/cm |
| Ni | 400.7 | 0.2 | Ω/cm |
| Al₂O₃ | 399.7 | 4000 | MΩ/cm or more |
| SiC (20% H₂/N₂) | 399.4 | 400 | kΩ/cm |
| Y₂O₃ | 397.0 | 4000 | MΩ/cm or more |
| SUS316L-EP | 390.1 | 0.2 | Ω/cm |
| Cr₂O₃—SUS | 389.3 | 0.2 | Ω/cm |

Carbon does not allow Alq3 molecules to be decomposed/dissociated up to 422.5° C., i.e. the highest temperature. Low-resistance SiC, TaN, AlN, BN, TiN, and MgO follow it. The material having as high a decomposition/dissociation start temperature as possible should be used for the evaporation dish and so on.

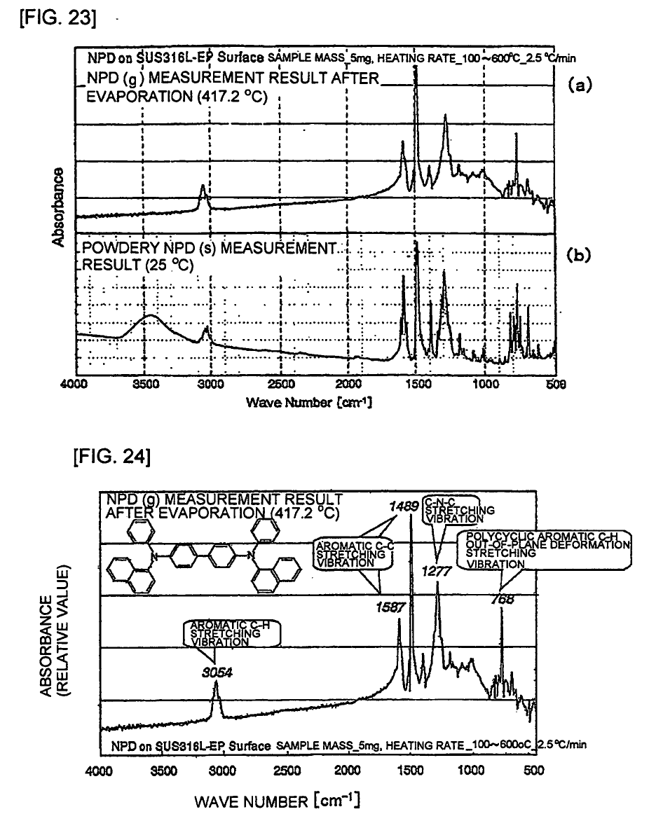

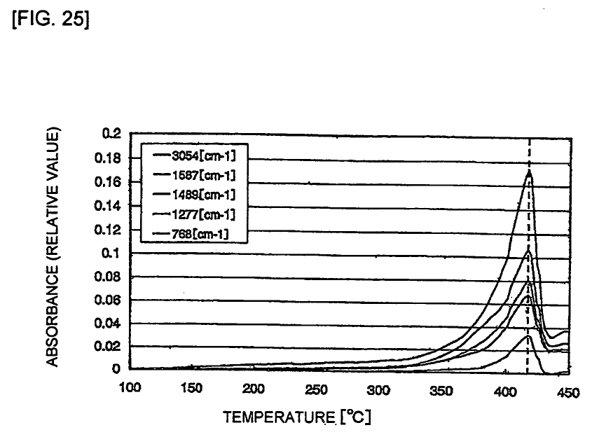

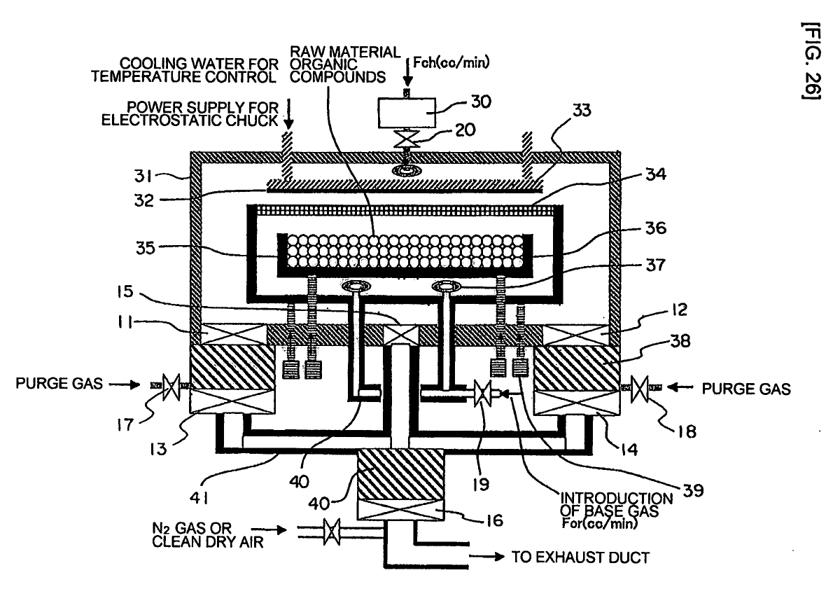

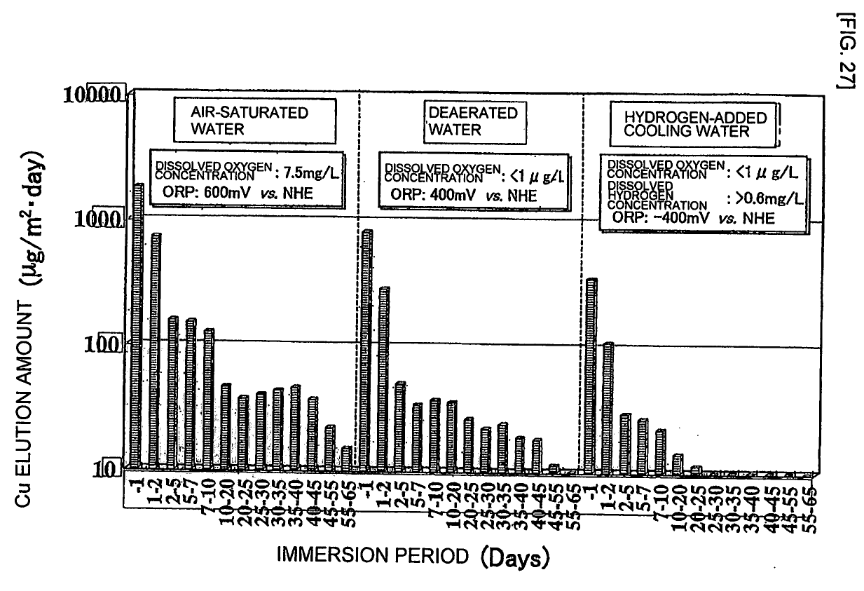

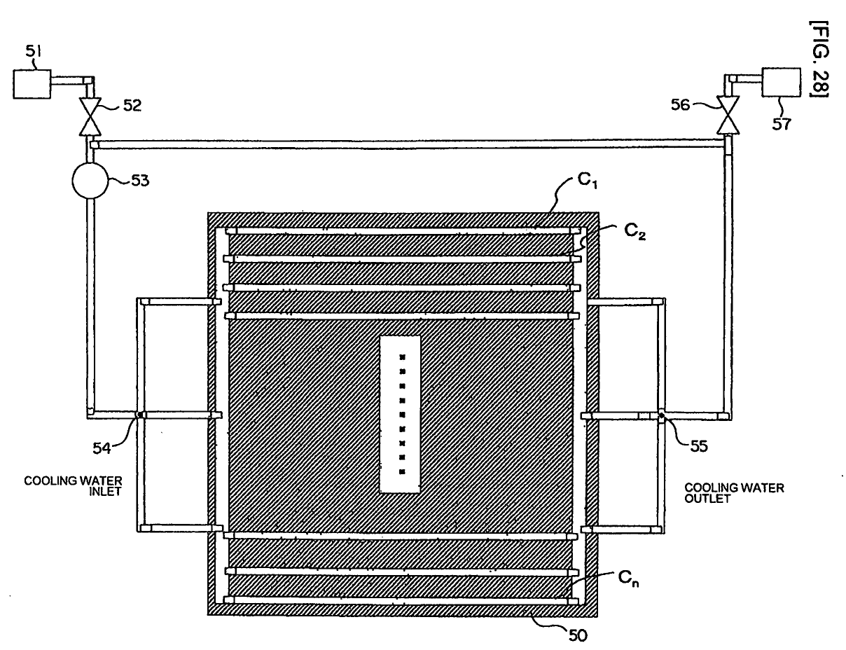

Next, description will be given with respect to NPD. At first, FIG. 23, (a) shows infrared absorption spectra of NPD molecules (C₄₄H₃₂N₂) evaporated at 417.2° C. by the use of an evaporation dish with an electrolytically polished SUS316L surface and FIG. 23, (b) shows infrared absorption spectra of solid NPD. Both infrared absorption behaviors well coincide with each other except behaviors near a wave number of 3500 cm⁻¹. FIG. 24 shows details of respective typical absorption spectra of NPD molecules evaporated into gas molecules. The difference in molecular structure from Alq3 appears as differences in respective absorption spectra. FIG. 25 shows the evaporation dish temperature dependence of absorbances at absorption peaks at respective wave numbers of 3054 cm⁻¹, 1587 cm⁻¹, 768 cm⁻¹, 1277 cm⁻¹, and 1489 cm⁻¹ of the absorption spectra in order from lower. When the temperature exceeds 417.2° C., all the absorption peaks rapidly decrease. This is because the NPD molecules start to be decomposed/dissociated due to the catalytic effect of the electrolytically polished SUS316 surface.

Table 3 shows temperatures at which NPD molecules start decomposition/dissociation, with respect to various materials. Like in the case of Alq3 molecules, the decomposition/dissociation start temperature by carbon is the highest, which is 452.8° C. High-resistance SiC, low-resistance SiC, AlN, MgO, Si₃N₄, and Al₂O₃ follow it.

[Table 3]

TABLE 3
Decomposition/Dissociation Start Temperatures
of NPD Molecules on Various Surfaces

| NPD | Temperature [° C.] | Resistance | |
|---|---|---|---|
| Carbon | 452.8 | 2 | Ω/cm |
| High-Resistance SiC | 431.5 | 10 | MΩ/cm |
| SiC | 426.2 | 400 | Ω/cm |
| AlN | 423.0 | 4000 | MΩ/cm or more |
| MgO | 420.1 | 4000 | MΩ/cm or more |
| Si₃N₄ | 418.8 | 4000 | MΩ/cm or more |
| Al₂O₃ | 417.9 | 4000 | MΩ/cm or more |
| SUS316L-EP | 417.2 | 0.2 | Ω/cm |
| Al₂O₃—SUS | 415.5 | 0.3 | Ω/cm |
| Ni | 414.4 | 0.2 | Ω/cm |
| TaN—SUS | 414.1 | 0.8 | Ω/cm |
| SiC (20% H₂/N₂) | 410.9 | 400 | kΩ/cm |
| Y₂O₃ | 408.3 | 4000 | MΩ/cm or more |
| Cr₂O₃—SUS | 407.2 | 0.2 | Ω/cm |
| BN | 403.7 | 4000 | MΩ/cm or more |
| TiN—SUS | 398.3 | 0.2 | Ω/cm |

### EMBODIMENT 1

Hereinbelow, Embodiment 1 of this invention will be described with reference to the drawings.

The materials each adapted to evaporate the organic EL material into the gas phase without decomposition/dissociation have been made clear. Description will be next given of an apparatus adapted to form a film of an expensive organic EL material on a glass substrate, plastic substrate, or metal substrate quite efficiently and at a high rate without decomposing/dissociating organic EL molecules.

Referring to FIG. 26, description will be given of the mechanism for evaporating an organic EL material with respect to a substrate 32 located in a process chamber (container to be depressurized) 31, thereby carrying out film formation on the substrate 32.

In FIG. 26, there are included valves 11 to 20, the process chamber 31, the substrate 32, a stage 33, a gas ejection plate 34, an organic compound molecule ejection apparatus 35, an evaporation dish 36, ring-shaped gas ejection portions 37, turbo-molecular pumps 38, a temperature control heater power supply 39, and a gas temperature control roughing vacuum pump 41.

Herein, it has been clarified as described before that various organic EL materials are each evaporated in a monomolecular state into the gas phase when heated to approximately 300° C. or more. Further, it has also been clarified that the material which most reluctantly decomposes/dissociates the organic EL molecules is carbon.

Although there are various types where the surface of the substrate 32 such as the glass substrate or the metal substrate faces downward, upward, and sideward, description will be first given of the structure where the substrate is located with the surface thereof facing downward. FIG. 26 shows a sectional view of an organic film-forming apparatus in which the substrate 32 is located so as to face downward.

The substrate 32 such as the glass substrate, the plastic substrate, or the metal substrate is held in tight contact with the stage 33 by substrate fixing means such as an electrostatic chuck so that the entire surface of the substrate is controlled uniformly and strictly at a temperature near room temperature. The surface temperature of the stage 33 is uniformly and strictly controlled by circulating, over the entire surface of the stage, hydrogen-added cooling water removed of N₂ and O₂ dissolved from the atmosphere and added with hydrogen (H₂) at saturation solubility or less, for example, in an amount of 0.5 to 1.4 ppm. The hydrogen-added water removed of N₂ and O₂ and added with H₂ has an oxidation-reduction potential (ORP) of −400 mV and thus is water shifting to the reduction side by indeed as much as 1V as compared with +600 mV, normally an ORP of water dissolved with N₂ and O₂ from the atmosphere, thereby not rusting metal or not breeding bacteria. Even if it is used for a long time in a hermetically sealed manner, the water quality is hardly degraded.

FIG. 27 shows the dissolution amount of metal into the hydrogen-added cooling water and, as comparison, shows the dissolution amounts of metal in air-saturated water and deaerated water being general cooling water. Cu is evaluated as the metal. It can be understood that the hydrogen-added cooling water has the effect of not corroding metal. Inside the substrate stage, a temperature control cooling water circulation system is constructed of copper or aluminum having high heat conductivity (high heat exchange efficiency) as shown in FIG. 28. In FIG. 28, there are included a substrate stage 50, flow rate controllers 51 and 57, valves 52 and 56, a compressor 53, and temperature sensors 54 and 55.

In order to control the temperature of the substrate surface at T₀ (° C.) near room temperature, the system is configured by keeping constant the cooling water amount flowing in the substrate stage 50, defining beforehand a correlation with a temperature T₁ (° C.) at a cooling water outlet by the temperature sensor 55 to be “T₀>T₁”, discharging a portion of outlet-side cooling water raised in temperature into a return cooling water pipe, and introducing the same amount of cooling water from a cooling water supply pipe on the left side, thereby circulating the cooling water to the substrate stage 50 by the use of a circulation motor.

The number (layout pitch) of temperature control cooling water pipes C₁, C₂, to Cₙ of the substrate stage 50 and the inner diameter thereof are determined in the following manner. That is, the number layout pitch) is determined so that the difference in temperature of the substrate surface is within ±1° C. and preferably within ±0.3° C. This temperature variation on the substrate surface is directly reflected on thickness variation of an organic film formed. For example, when the substrate temperature is 30° C., the temperature difference of ±0.3° C. corresponds to a temperature variation of 1%. The inner diameter of the cooling water pipe is set to a narrow inner diameter in a region where the cooling water forms slightly turbulent flow and not laminar flow so that the cooling water flowing inside the pipe efficiently carries out heat exchange with respect to the wall surface of the pipe. If the inner diameter is too narrow so that the cooling water forms excessively strong turbulent flow, although the heat exchange efficiency increases, the pressure drop for forcing the cooling water to flow becomes too large. Therefore, the load of a cooling water circulation pump becomes too large and hence the power consumption of the entire system becomes excessive. As a result, the Reynolds number of the cooling water flowing in the cooling water pipe is desirably set in the range of 1000 to 7000. In order to reduce the pressure drop and shorten a time in which the cooling water flows through the stage, the cooling water pipes C₁, C₂, to Cₙ are arranged in parallel. Unless the same amount of the cooling water flows in all the cooling water pipes, the temperature of the substrate surface is not maintained uniform.

The inner diameter of the cooling water pipe should be controlled quite accurately. The inner diameter should be controlled with an accuracy within ±1%. The size of a large-area substrate subjected to organic film formation is 1 m, 2 m, . . . , or 5 m or more. Therefore, the substrate stage becomes quite large. It is not easy to accurately control the inner diameter of a long narrow pipe. Even in that case, the cooling water amount flowing in all the cooling water pipes should be the same. Assuming that the flow rate is constant, a pressure drop Pd of cooling water in a region of slightly turbulent flow depends on an inner diameter D and a length L of a cooling water pipe as follows.

Pd∝L/D^{α}

In a turbulent flow region,

Pd∝L/D^{β}

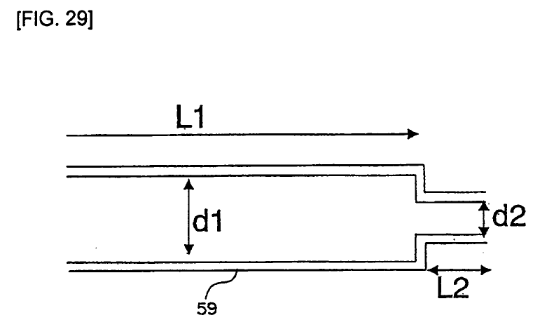

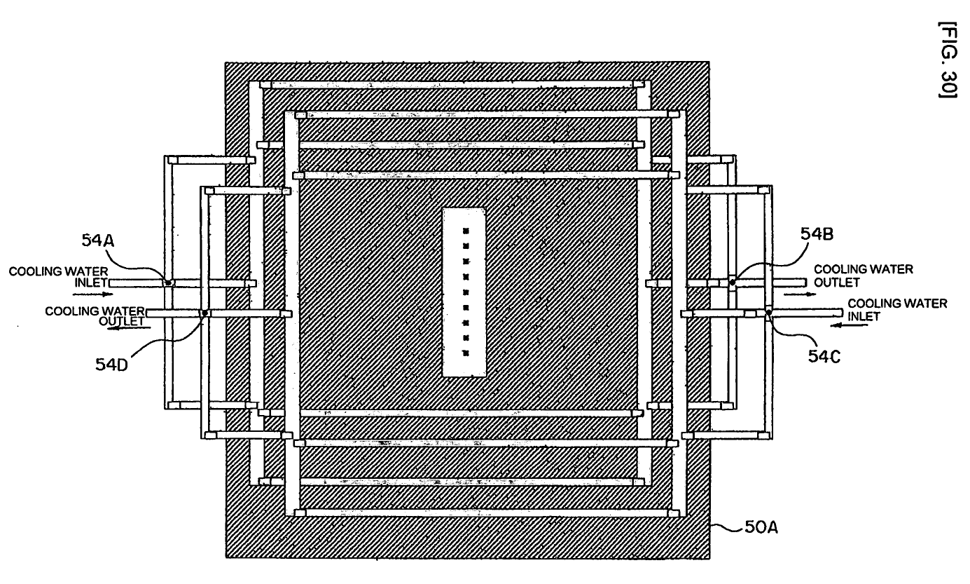

Therefore, inner diameter variations are respectively raised to the a powers and the β powers, thereby leading to changes in pressure drop so as to be directly reflected on changes in flow rate. Herein, α=2 and β=approximately 1.25. In order to solve this problem, at an inlet portion or an outlet portion of each cooling water pipe 59, a narrow pipe portion having an inner diameter d2 smaller than an inner diameter d1 of the cooling water pipe having a length L1 may be provided by a very short length L2 as shown in FIG. 29.

The inner diameter of this narrow pipe portion with the short length L2 is finished to an accuracy within ±0.3%. A total pressure drop Pt of this pipe is the sum of a pressure drop Pt1 at the cooling water pipe portion and a pressure drop Pt2 at the narrow pipe portion.

Pt∝L1/D1^{α}+L2/D2^{β}

By setting the narrow pipe portion pressure drop L2/D2^{β} to be greater than the cooling water pipe portion pressure drop L1/D1^{α}, pressure drop variation is determined only by the narrow pipe portion inner diameter accuracy, so that in all the cooling water pipes the cooling water amount for each pipe can be the same. The inner diameter of a narrow pipe having a very short length can be controlled, for example, at approximately ±0.1%.

FIG. 30 shows the case where a substrate increases in size so that a substrate stage 50A increases in size to 2 m or 5 m. In this case, the substrate stage passing time of cooling water flowing in cooling water pipes increases so that there occurs a difference between left and right temperatures of the substrate stage 50 shown in FIG. 28. In such a case, like cooling water pipes shown in FIG. 30, by alternating cooling water flowing directions one by one so that the cooling water flows in opposite directions, i.e. right and left directions, uniformity in temperature of the entire surface of the substrate is improved. The technique of equalizing the temperature of the substrate surface has been described in detail. Variation in organic film thickness due to variation in substrate surface temperature is completely suppressed by this.

Next, an organic film-forming method will be described. In FIG. 26, the organic compound molecule ejection apparatus 35 is comprised of carbon that does not decompose/dissociate organic compound molecules up to the highest temperature as described before, SiC, or the like. An organic EL material or organic compound serving as a raw material is removed of adsorbed/occluded moisture and oxygen in a high purity N₂ atmosphere at a temperature of approximately 100° C. to 220° C. and then is located in the evaporation dish 36 located in the organic compound molecule ejection apparatus 35. The evaporation dish 36 is provided with a heater so as to be raised in temperature, thereby evaporating organic EL or organic compound molecules. The temperature of the wall surfaces of the organic compound molecule ejection apparatus 35 and the ejection plate surrounding the evaporation dish 36 is set higher than the temperature of the evaporation dish 36 in order to prevent adsorption of organic compound molecules evaporated from the evaporation dish 36. Normally, it is set higher by 20° C. to 30° C. For example, it is like when the raw material is Alq3 and the constituent material of the wall surfaces and the ejection plate is carbon, since the decomposition/dissociation temperature of the raw material is 422° C., the temperature of the evaporation dish 36 is set to 370° C. to 390° C. and the temperature of the outer peripheral portions (the wall surfaces and the ejection plate) is set to 400° C. to 410° C.

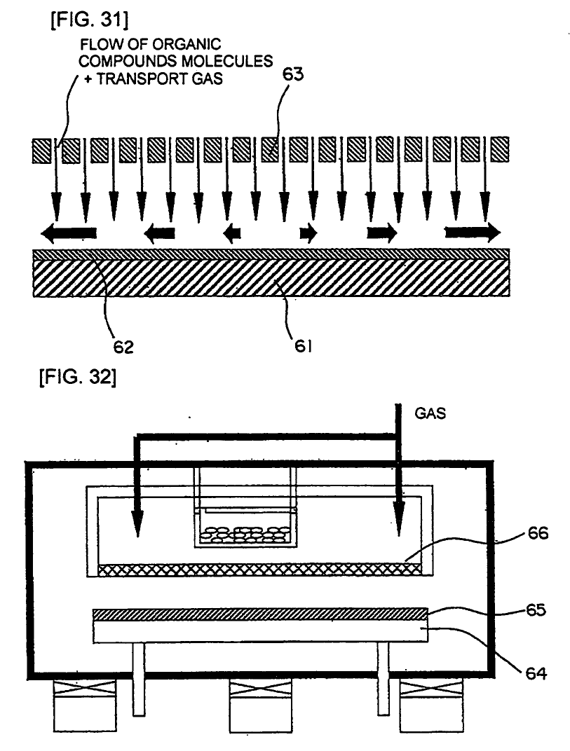

The evaporated organic compound molecules are confined inside the organic compound molecule ejection apparatus 35 (FIG. 26). As shown in FIG. 31, an organic compound molecule ejection plate 63 facing a substrate 61 is comprised of a porous material or has a shower plate structure. Naturally, the material has a high decomposition/dissociation temperature for organic compound molecules. The evaporation dish 36 (FIG. 26) has a small heat capacity so that, for example, its temperature can be changed between 270° C. to 300° C. (the state where organic compound molecules are not evaporated) and 370° C. to 390° C. (the state where organic compound molecules are evaporated) in a short time. The temperature of the outer peripheral portions is held constant. During non-film formation, the temperature of the evaporation dish 36 shown in FIG. 26 is set to a non-evaporation state, wherein the valves 11 and 12 are closed while the valve 15 is opened and the pressure inside the chamber 31 is held in a viscous flow region of 1 to 10 Torr by a gas flow rate Fch (cc/min) of Ar, N₂, or the like flowing in from the upper portion of the chamber 31. During film formation, the evaporation dish temperature is set to an organic compound evaporation state (high temperature), wherein the valve 15 is closed, the valves 11 and 12 are opened, and the valve 20 is closed to make Fch zero, while the valve 19 is opened to supply an inert gas at approximately 100 cc/min to 1,000 cc/min into the organic compound molecule ejection apparatus 35, thereby ejecting a gas toward the substrate 32 through the ejection plate (porous plate or shower plate) 34.

The ejected gas contains evaporated organic compound molecules so that the organic compound molecules are adsorbed on the substrate surface controlled at a temperature near room temperature. When the substrate has a large area, a gas having a mass greater than Ar with mass number 40 is desirable for accurately forming a gas flow pattern. Kr with mass number 80, Xe with mass number 131, or particularly krypton Kr is preferable. Naturally, it may also be a mixed gas of Ar and Kr or Ar and Xe. The organic compound molecule ejection gas is heated to the same temperature as that of the evaporation dish 36 by a heater before flowing into the organic compound molecule ejection apparatus 35. This is for preventing occurrence of change in temperature of the evaporation dish 36. The pressure inside the chamber 31 during organic film formation is set to a transition flow region of approximately several mTorr to 0.1 mTorr or less. This is the range where the mean free path of gas molecules is several mm to several tens of centimeters.

At the stage where an organic film having a predetermined thickness is formed on the substrate surface, the organic compound molecule ejection gas is stopped and the temperature of the evaporation dish is dropped to the temperature of the non-film formation state. When the film formation is finished, the valves 11 and 12 are closed, the valve 15 is opened, and the valve 20 is opened to introduce the gas such as Ar or N₂, thereby setting the pressure inside the chamber to approximately 1 to 10 Torr. In order to achieve the pressure balance between the inside of the organic compound molecule ejection apparatus and the inside of the chamber, it is effective to feed a small amount of gas inside the organic compound molecule ejection apparatus.

In a general substrate transfer system, a substrate is transferred while its surface to be formed with an element thereon faces upward. A complicated system is required for rotating downward, as shown in FIG. 26, a large-area substrate that is evenly and horizontally transferred with the surface thereof facing upward. If the surface of a substrate faces upward or a substrate is stood upright, its system is relatively simple.

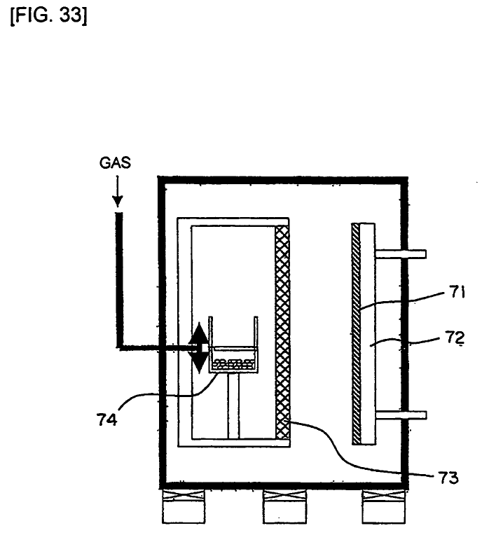

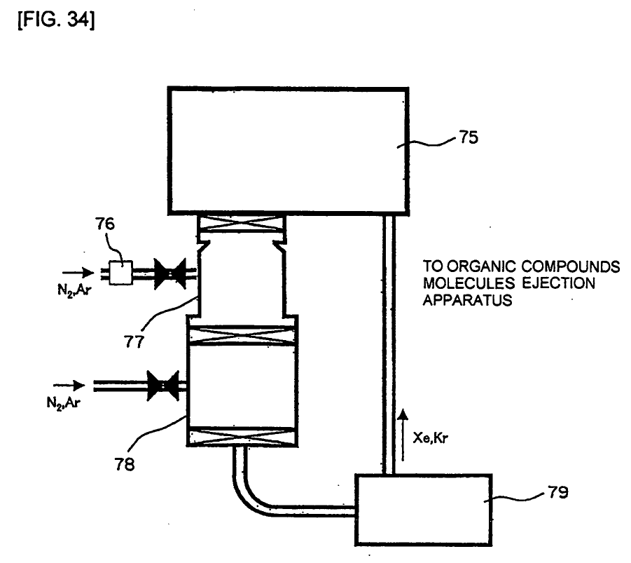

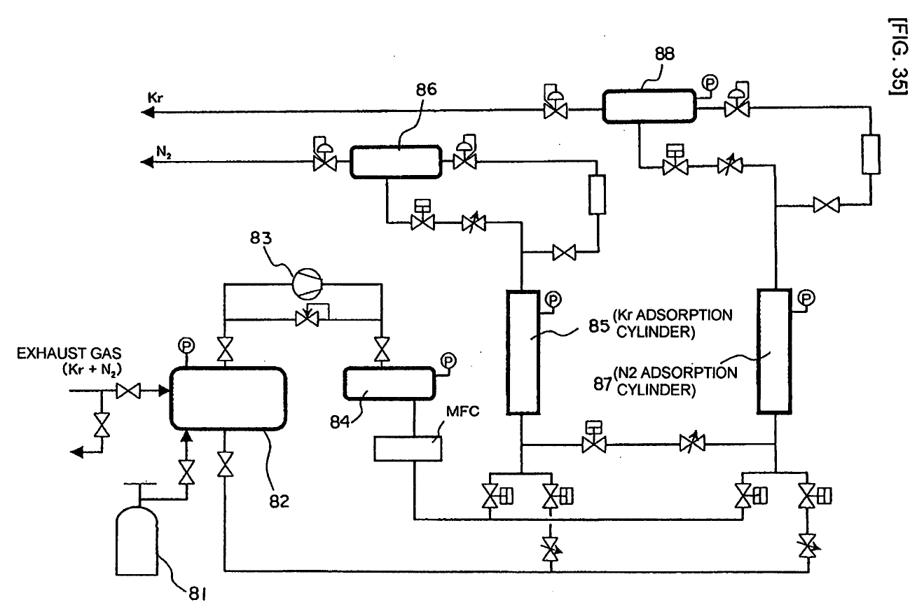

FIG. 32 shows the structure where a substrate 65 is located on a stage 64 so as to face upward and is opposed to an ejection plate 66. Further, FIG. 33 shows a sectional view of a film-forming apparatus adapted to carry out organic film formation with a structure in which a substrate 71 stood substantially vertically is located on a stage 72 and faces an ejection plate 73 and an evaporation dish 74 is disposed on the back side of the ejection plate 73. In either case, except that the direction of the substrate surface differs, the same structure, operation, and effect can be achieved as those of the apparatus of FIG. 26 with the substrate facing downward and, therefore, detailed explanation thereof is omitted.

As described before, even in the case of a single-color organic EL layer, it is necessary to form a plurality of film layers. In order to successively form the plurality of film layers, a plurality of organic compound ejection apparatuses as shown in FIG. 26 are juxtaposed so as to be aligned laterally inside the same chamber (container to be depressurized) and a substrate is configured to be movable over them (under them in the case of FIG. 32 and on the side of them in the case of FIG. 33) in parallel thereto in an alignment direction. Then, the substrate is stopped over (or under or on the side of) the first organic compound ejection apparatus and a first organic compound gas is ejected from the first organic compound ejection apparatus, thereby forming a film of a first organic compound layer on the substrate, and then, the substrate is automatically transferred and stopped over (or under or on the side of) the second organic compound ejection apparatus located adjacent to the first organic compound ejection apparatus and a second organic compound gas is ejected from the second organic compound ejection apparatus, thereby forming a film of a second organic compound layer on the first organic compound layer on the substrate. By carrying out in the same manner thereafter, the plurality of organic compound layers can be successively formed in the same chamber.

### EMBODIMENT 2

When organic compound molecules having a certain weight, i.e. a molecular weight of several hundreds to approximately 1000, are contained in a heavy base gas such as Xe or Kr and irradiated onto a substrate, the gas flow accurately reaches the substrate surface, which is thus more preferable. The organic compound molecules, which are solidified near room temperature, are adsorbed on the substrate surface and only the Xe gas or Kr gas is discharged to the outside by the exhaust pumps. Xe and Kr are highly expensive gases as compared with Ar and N₂ that are normally used industrially. It is desirable that a Xe or Kr recovery circulation system be provided subsequently to the roughing vacuum pump.

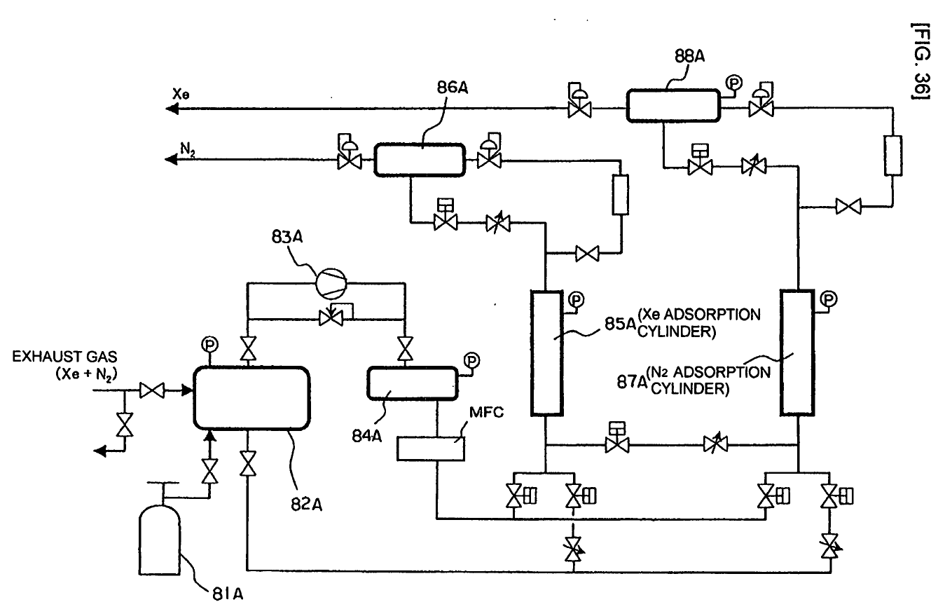

FIG. 34 shows a system for recovering/circulating an Xe gas or a Kr gas. In FIG. 34, a turbo-molecular pump 77 coupled to a chamber 75 through a valve is coupled to a roughing vacuum pump 78 and the turbo-molecular pump 77 and the roughing vacuum pump 78 receive Ar or N₂ and exhaust it to a recovery apparatus 79, thereby recovering the Xe gas or Kr gas.

In order to achieve the Xe gas or Kr gas recovery efficiency of 99.99% or more or 99.9% or more, the flow rate of the purge gas to the turbo-molecular pump 77 and the roughing vacuum pump 78 should be set equal to or less than that of the Xe gas or the Kr gas. Naturally, it should be necessary to prevent incorporation of evaporated components from grease used for bearings and so on of the pumps.

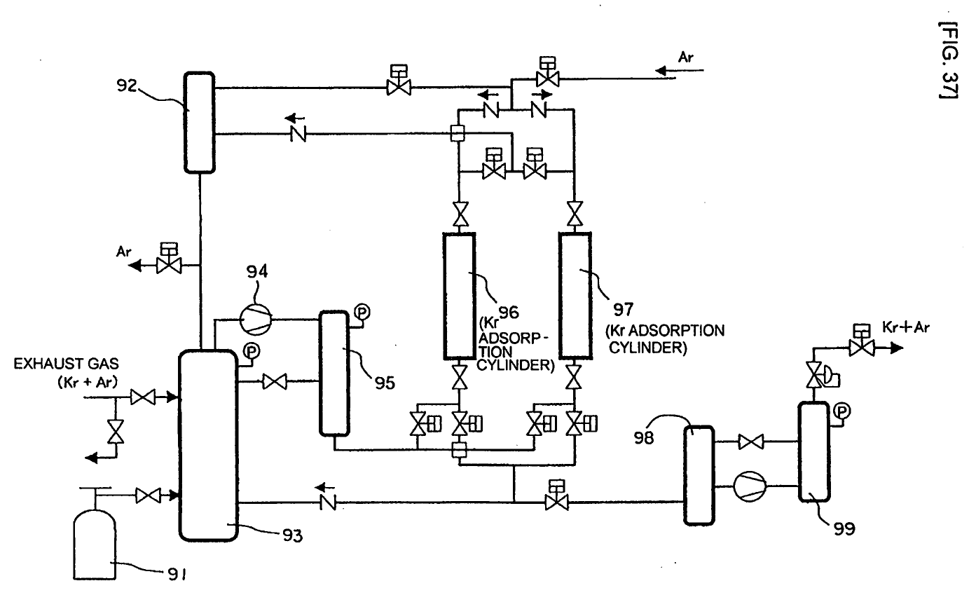

FIGS. 35 and 36 are diagrams showing the structures of Kr and Xe circulation supply apparatuses, respectively. In FIG. 35, there are included a supplementary Kr bomb 81, a low-pressure raw material tank 82, a diaphragm compressor 83, a high-pressure raw material tank 84, a GL1 (Kr adsorption cylinder) 85, a GL1 product tank 86, a GL2 (N₂ adsorption cylinder) 87, and a GL2 product tank 88. Similarly, in FIG. 36, there are included a supplementary Xe bomb 81A, a low-pressure raw material tank 82A, a diaphragm compressor 83A, a high-pressure raw material tank 84A, a GL1 (Xe adsorption cylinder) 85A, a GL1 product tank 86A, a GL2 (N₂ adsorption cylinder) 87A, and a GL2 product tank 88A.

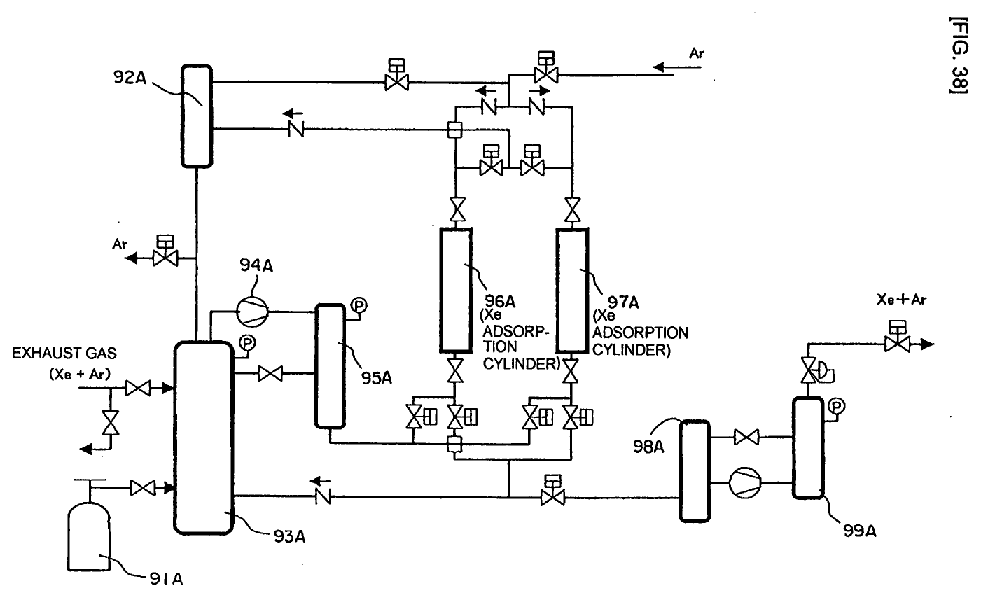

Further, FIGS. 37 and 38 are diagrams showing the structures of circulation supply apparatuses for mixed gases of Ar and Kr, and Ar and Xe, respectively. In FIG. 37, there are included a supplementary Kr bomb 91, an Ar buffer tank 92, a low-pressure raw material tank 93, a diaphragm compressor 94, a high-pressure raw material tank 95, a GL1-1 (Kr adsorption cylinder) 96, a GL1-2 (Kr adsorption cylinder) 97, a “Kr+Ar” buffer tank 98, and a “Kr+Ar” product tank 99. Similarly, in FIG. 38, there are included a supplementary Xe bomb 91A, an Ar buffer tank 92A, a low-pressure raw material tank 93A, a diaphragm compressor 94A, a high-pressure raw material tank 95A, a GL1-1 (Xe adsorption cylinder) 96A, a GL1-2 (Xe adsorption cylinder) 97A, a “Xe+Ar” buffer tank 98A, and a “Xe+Ar” product tank 99A.

In each of them, the adsorption cylinder is provided therein with an adsorbent for adsorbing impurities such as noble gas components or nitrogen and Xe or Kr is separated/purified by changing the pressure inside the adsorption cylinder to repeat adsorption/desorption.

### EMBODIMENT 3

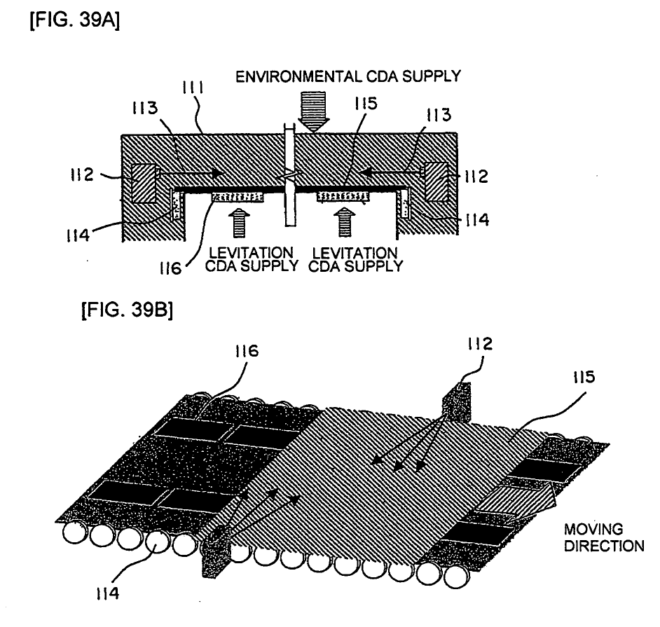

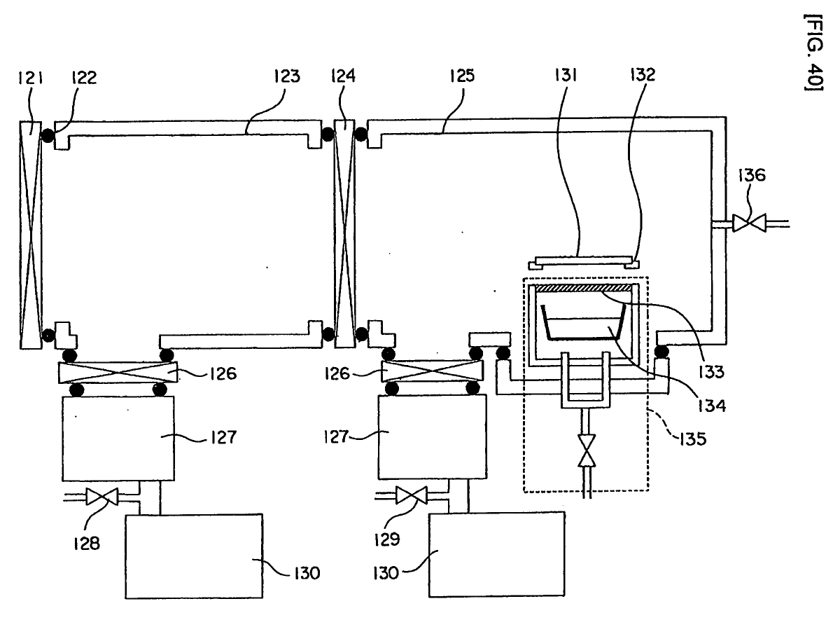

The lifetime and luminous properties of an organic EL element can be improved by removing organic compound contamination of an organic EL thin film. On the other hand, when transferring a glass substrate to a film-forming apparatus after cleaning, if use is comprised of a transfer apparatus that does not cause organic contamination on the substrate surface, the lifetime and luminous properties can be further improved. For such transfer of the glass substrate, it is most desirable to transfer the substrate, facing upward or downward, by gas levitation transfer with a clean dry air using porous ceramics as shown in FIG. 39 as an example. As shown in Embodiment 1 as the examples, when the substrate surface (the surface to be deposited with a film-forming material) faces upward in the film-forming apparatus, it is preferable that the substrate surface face upward during gas levitation transfer, when the substrate surface faces downward in the film-forming apparatus, it is preferable that the substrate surface face downward during gas levitation transfer, and when the substrate is stood substantially upright in the film-forming apparatus, it is preferable that the substrate surface face upward or downward during gas levitation transfer.

FIGS. 39A and 39B show an example where a substrate is transferred to a film-forming apparatus by the use of a gas levitation transfer system using a clean dry air. In FIGS. 39A and 39B, there are included a casing 111, soft X-ray ionizers 112, soft X-rays 113, driving rollers 114, a glass substrate 115, and levitation ceramics 116.

Since the substrate is levitated/transferred in a clean dry air atmosphere containing no moisture or no organic compound, not only ultrahigh-quality film formation is enabled because moisture or organic compound are not adsorbed at all on the outermost surface of the substrate, but also static electricity is not carried at all in gas levitation transfer using porous ceramics and, therefore, a problem such as dielectric breakdown or disconnection in an element or at element peripheral portions can be reduced, thereby enabling an improvement in production yield and a reduction in production cost.

### EMBODIMENT 4

A film-forming apparatus in Embodiment 4 of this invention will be described with reference to FIG. 40. FIG. 40 is a sectional view showing one example of a deposition apparatus of this Embodiment 4, wherein the apparatus mainly comprises a container forming a process chamber 125 adapted to carry out a film-forming process, a substrate introduction chamber 123 coupled to the process chamber 125 through a gate valve 124 serving as a partition for the depressurizing chamber and maintaining air-tightness of the process chamber 125, so as to carry in and out a substrate 131, a substrate introduction door 121 coupled to the substrate introduction chamber 123, a substrate holder 132 adapted to hold the substrate 131 in the container, primary pumps 127 coupled to the depressurizing chamber and the substrate introduction chamber 123 through pump gate valves 126, respectively, secondary pumps 130 coupled to exhaust sides of the primary pumps 127, pump purge gas introduction mechanisms 128 and 129 each located between the primary pump 127 and the secondary pump 130 for suppressing back diffusion of impurities from the secondary pump 130, and film-forming material supply means 135 coupled to the container for supplying a film-forming material 134 or a film-forming material precursor, and further comprises substrate placing means provided in the depressurizing chamber for placing the substrate 131 to be deposited with the film-forming material, film-forming material ejection means located so as to face the substrate 131 for ejecting the film-forming material 134 or the film-forming material precursor, supplied from the film-forming material supply means 135, toward the substrate surface, and gaskets 122 provided at connecting portions of the respective members for maintaining air tightness to the exterior.

Among them, in the film-forming apparatus in this embodiment, the gaskets 122 provided between the substrate introduction door 121 and the substrate introduction chamber 123 and between a deposition source chamber and a shutter mechanism are comprised of perfluoroelastomer and the other gaskets are comprised of Cu. By this configuration, it is possible to minimize the number of gaskets containing the organic compound and, further, even the gaskets containing the organic compound use the material whose organic compound release is very little, and therefore, it is possible to suppress incorporation of impurities, released from the gaskets, into an organic compound thin film formed on the substrate. Further, the deposition source container is comprised of Al₂O₃ and its inner surfaces are made substantially flat by polishing, and therefore, there is almost no catalysis so that it is possible to suppress thermal decomposition of the deposition material inside the deposition source container.

As a result of forming an organic EL layer by the use of this deposition apparatus and measuring the properties of an organic EL element, the brightness at the same current was improved by 30% as compared with the case of using conventional ones (general fluororubber gaskets and a general deposition source container) and the luminance half-decay lifetime became twice, i.e. 10000 hours. Since the organic compound release from the gaskets is suppressed and the decomposition of the deposition material in the deposition source container is suppressed, the incorporation of the impurities into the organic EL layer is suppressed. Therefore, it was possible to improve the brightness and the lifetime.

### INDUSTRIAL APPLICABILITY

According to this invention, since an evaporated film-forming material reaches the surface of a substrate by the flow of a transport gas, the film-forming conditions can be controlled by the flow of the gas and hence a uniform thin film can be deposited on the large-area substrate. The film-forming apparatus of this invention thoroughly eliminates generation of the organic compound contamination substance/material decomposition dissociation substance that adversely affects the properties of the film-forming material, and thus can deposit a high-quality thin film. By using the film-forming apparatus and the film-forming method of this invention for forming an organic EL element, it is possible to obtain a high-quality organic EL display device with high brightness and long lifetime. The film-forming apparatus and the film-forming method of this invention are effectively applicable not only to the organic EL field but also to all the other fields where raw materials are evaporated to form films with respect to flat panel display devices, semiconductor devices, and other general electronic devices.

1. A film-forming apparatus characterized by comprising a container to be depressurized, a depressurizing mechanism directly or indirectly coupled to said container, a film-forming material supply apparatus located inside or outside said container and directly or indirectly coupled to said container for supplying a film-forming material or a film-forming material precursor, and a substrate-placing portion located in said container for placing a substrate on which the film-forming material is deposited, wherein said film-forming material supply apparatus has at least an evaporation mechanism for evaporating said film-forming material or said film-forming material precursor and a portion of said evaporation mechanism, to which said film-forming material or said film-forming material precursor is to be contacted, is composed of a material having a low gas discharge or a material having a low catalytic effect.

2. A film-forming apparatus according to claim 1, characterized by comprising a transport gas-supplying mechanism for supplying a gas that transports the evaporated film-forming material or film-forming material precursor to a surface of said substrate.

3. A film-forming apparatus according to claim 1, characterized in that said evaporation mechanism comprises a heating mechanism for heating said film-forming material or said film-forming material precursor to a first temperature equal to or higher than an evaporation temperature at which said film-forming material or said film-forming material precursor is evaporated, and a predetermined portion inside said container is heated to a second temperature exceeding said evaporation temperature.

4. A film-forming apparatus according to claim 3, characterized in that a temperature of said substrate is maintained at a third temperature lower than said evaporation temperature.

5. A film-forming apparatus according to claim 3, characterized in that said first temperature and said second temperature are lower than a temperature at which the evaporated film-forming material or film-forming material precursor is decomposed.

6. A film-forming apparatus according to claim 3, characterized in that said second temperature is higher than said first temperature.

7. A film-forming apparatus according to claim 3, characterized in that said second temperature is higher than said first temperature by 20° C. or more.

8. A film-forming apparatus according to claim 4, characterized in that said third temperature is equal to or lower than said evaporation temperature.

9. A film-forming apparatus according to claim 8, characterized in that said film-forming material is a material for organic EL and said third temperature is less than 100° C.

10. A film-forming apparatus according to claim 3, characterized in that said predetermined portion is a portion adapted to contact the evaporated film-forming material or film-forming material precursor and excluding said substrate and said substrate holding portion.

11. A film-forming apparatus according to claim 2, characterized in that said transport gas-supplying mechanism comprises a portion adapted to introduce said transport gas from the outside into a container holding said film-forming material or said film-forming material precursor and a gas ejection portion having a plurality of small holes and located so as to face said substrate, and said gas transports said evaporated film-forming material or film-forming material precursor to the surface of said substrate through said gas ejection portion.

12. A film-forming apparatus according to claim 2, characterized in that said transport gas-supplying mechanism comprises a mechanism for supplying said transport gas from the outside so as to contact said evaporated film-forming material or film-forming material precursor and a mechanism for ejecting the transport gas containing said evaporated film-forming material or film-forming material precursor toward said substrate.

13. A film-forming apparatus according to claim 12, characterized in that said mechanism for ejecting comprises a shower plate or a plate comprised of a porous material.

14. A film-forming apparatus according to claim 1, characterized in that said evaporation mechanism is configured to evaporate said film-forming material or said film-forming material precursor during execution of film formation and to stop evaporation during non-execution of film formation.

15. A film-forming apparatus according to claim 1, characterized in that said depressurizing mechanism maintains the inside of said container at a pressure of 10 mTorr to 0.1 mTorr during execution of film formation.

16. A film-forming apparatus according to claim 15, characterized in that said depressurizing means causes a gas flow in said container to be in a molecular flow region during the execution of film formation and causes a gas flow in said container to be in an intermediate flow region or a viscous flow region at least for a certain period during non-execution of film formation.

17. A film-forming apparatus according to claim 12, characterized in that said gas is a xenon (Xe) gas.

18. A film-forming apparatus according to claim 2, characterized in that said gas contains an inert gas as a main component.

19. A film-forming apparatus according to claim 2, characterized in that said gas contains at least one of nitrogen (N), Xe, Kr, Ar, Ne, and He.

20. A film-forming apparatus according to claim 1, characterized in that said depressurizing mechanism comprises a turbo-molecular pump and a roughing vacuum pump and a portion for supplying an inert gas is provided between said turbo-molecular pump and said roughing vacuum pump.

21. A film-forming apparatus coupled to a substrate transfer apparatus, said film-forming apparatus characterized in that an air having a dew point temperature of −80° C. or less is supplied to a space inside said substrate transfer apparatus.

22. A film-forming apparatus according to claim 1, characterized in that a pressure in said container during film formation and that during non-film formation are in a molecular flow pressure region and an intermediate flow pressure region or a viscous flow pressure region, respectively.

23. An organic EL device having an organic EL layer formed by the use of the film-forming apparatus according to claim 12.

24. An electronic device having a film layer of a predetermined material formed by the use of the film-forming apparatus according to claim 12.

25. An apparatus for processing under a depressurized condition, characterized by comprising a container to be depressurized, a primary pump coupled to said container, a secondary pump coupled to an exhaust side of said primary pump, and a process object-introducing door coupled to said container through a gasket, wherein at least said gasket is comprised of a material having a low discharge of an organic gas.

26. An apparatus according to claim 25, characterized in that said gasket contains organic compound.

27. An apparatus according to claim 25, characterized in that said gasket has been subjected to a step of contacting said gasket with water of 80° C. or more.

28. An apparatus according to claim 26, characterized in that a main component of said organic compound is a perfluoroelastomer.

29. An apparatus according to claim 25, characterized by comprising, in addition to said gasket, a plurality of gaskets adapted to maintain airtightness of said container, wherein the gasket adapted to maintain the air-tightness at a portion with a low attaching/detaching frequency is comprised of metal.

30. An apparatus according to claim 29, characterized in that the gasket adapted to maintain the air-tightness at a portion with a high attaching/detaching frequency contains organic compound.

31. An apparatus according to claim 30, characterized in that said gasket containing the organic compound has been subjected to a step of contacting said gasket with water of 80° C. or more.

32. An apparatus according to claim 30, characterized in that a main component of said organic compound is a perfluoroelastomer.

33. A film-forming method for depositing a film of a predetermined material on a substrate in a container, said film-forming method characterized by comprising a step of evaporating a raw material used for forming said film of the predetermined material and a step of transporting the evaporated raw material to a surface of said substrate by the use of a gas.

34. A film-forming method according to claim 33, characterized in that said evaporating step comprises a step of heating said raw material to a first temperature equal to or higher than a temperature at which said raw material is evaporated, and a step of heating a predetermined portion inside said container to a second temperature exceeding said temperature at which said raw material is evaporated.

35. A film-forming method according to claim 34, characterized in that a temperature of said substrate is maintained at a third temperature lower than said temperature at which said raw material is evaporated.

36. A film-forming method according to claim 34, characterized in that said first temperature and said second temperature are lower than a temperature at which the evaporated raw material is decomposed.

37. A film-forming method according to claim 36, characterized in that said second temperature is higher than said first temperature.

38. A film-forming method according to claim 36, characterized in that said second temperature is higher than said first temperature by 20° C. or more.

39. A film-forming method according to claim 35, characterized in that said third temperature is equal to or lower than said temperature at which said raw material is evaporated.

40. A film-forming method according to claim 35, characterized in that said predetermined material is an organic EL material and said third temperature is less than 100° C.

41. A film-forming method according to claim 34, characterized in that said predetermined portion is a portion adapted to contact said evaporated raw material and excluding said substrate.

42. A film-forming method according to claim 33, characterized in that said raw material is said predetermined material or a precursor of said predetermined material.

43. A film-forming method according to claim 33, characterized by placing said raw material in a heat-resistant container, placing said heat-resistant container in a gas container, introducing said gas into said gas container to transport said evaporated raw material by the use of said gas, and causing said gas to reach the surface of said substrate through a gas ejection portion while transporting said evaporated raw material, wherein said gas ejection portion having a plurality of small holes is provided so as to face said substrate.

44. A film-forming method according to claim 33, characterized by maintaining the inside of said container at a pressure of 10 mTorr to 0.1 mTorr during execution of film formation and maintaining the inside of said container at a reduced pressure of 1 Torr or more at least for a certain period during non-execution of film formation.

45. A film-forming method according to claim 33, characterized by causing a gas flow in said container to be in a molecular flow region during execution of film formation and causing a gas flow in said container to be in an intermediate flow region or a viscous flow region at least for a certain period during non-execution of film formation.

46. A film-forming method according to claim 33, characterized in that said gas is a xenon (Xe) gas.

47. A film-forming method according to claim 33, characterized in that said gas contains an inert gas as a main component.

48. A film-forming method according to claim 47, characterized in that said inert gas contains at least one of nitrogen (N), Xe, Kr, Ar, Ne, and He.

49. A film-forming method according to claim 33, characterized in that said predetermined material is an organic EL element material.

50. An organic EL device manufacturing method characterized by comprising a step of forming a film of an organic EL element material by the use of the film-forming method according to claim 33.

51. An electronic device manufacturing method characterized by comprising a step of forming a film layer of a predetermined material by the use of the film-forming method according to claim 33.

52. An organic EL device having an organic EL layer formed by the use of the film-forming method according to claim 33.

53. An electronic device having a layer of a predetermined material formed by the use of the film-forming method according to claim 33.
